(19) United States
(12) Patent Application Publication
(10) Pub. No.: US 2024/0213196 A1
(43) Pub. Date: Jun. 27, 2024

(54) Power Semiconductor Devices Including Multiple Layer Metallization

(71) Applicant: Wolfspeed, Inc., Durham, NC (US)

(72) Inventors: Thomas Edgar Harrington, III, Durham, NC (US); Brice McPherson, Fayetteville, AR (US); Scott Allen, Durham, NC (US)

(21) Appl. No.: 18/160,765

(22) Filed: Jan. 27, 2023

Related U.S. Application Data
(60) Provisional application No. 63/434,782, filed on Dec. 22, 2022.

(51) Int. Cl. H01L 23/00; H01L 21/66; H01L 23/522

(52) U.S. Cl. CPC H01L 24/09; H01L 22/32; H01L 23/5226; H01L 24/03; H01L 2224/03; H01L 2224/0903; H01L 2224/09051; H01L 2924/10272; H01L 2924/13091

(57) ABSTRACT

Power semiconductor devices are provided. In one example, a semiconductor device includes a semiconductor vertical power device structure. The semiconductor device includes a first metallization layer on the semiconductor structure. The first metallization layer includes one or more metal structures. The semiconductor device includes a second metallization layer at least partially overlapping the first metallization layer. The semiconductor device includes an insulating layer between the first metallization layer and the second metallization layer. The insulating layer includes an insulating portion. The insulating portion may be patterned to insulate the one or more metal structures of the first metallization layer.

### PRIORITY CLAIM

The present application is based on and claims priority to U.S. Provisional Application 63/434,782 having a filing date of Dec. 22, 2022, which is incorporated by reference herein.

### FIELD

The present disclosure relates generally to power semiconductor devices.

### BACKGROUND

A wide variety of power semiconductor devices are known in the art including, for example, power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials such as silicon carbide or gallium nitride-based materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

### SUMMARY

Aspects and advantages of embodiments of the present disclosure will be set forth in part in the following description, or may be learned from the description, or may be learned through practice of the embodiments.

One example aspect of the present disclosure is directed to a semiconductor device. The semiconductor device includes a semiconductor vertical power device structure. The semiconductor device a first metallization layer on the semiconductor structure. The first metallization layer may include one or more metal structures. The semiconductor device includes a second metallization layer at least partially overlapping the first metallization layer. The semiconductor device includes an insulating layer between the first metallization layer and the second metallization layer. The insulating layer may include an insulating portion. The insulating portion may be patterned to insulate the one or more metal structures of the first metallization layer.

Another example aspect of the present disclosure is directed to a semiconductor device. The semiconductor device includes a semiconductor structure. The semiconductor device includes a first metallization layer on the semiconductor structure. The first metallization layer includes one or more metal structures. The semiconductor device includes a second metallization layer at least partially overlapping the first metallization layer. The semiconductor device includes a third metallization layer between the first metallization layer and the second metallization layer. The semiconductor device includes a first insulating layer between the first metallization layer and the third metallization layer. The semiconductor device includes a second insulating layer between the third metallization layer and the second metallization layer.

Another example aspect of the present disclosure is directed to a semiconductor device. The semiconductor device includes a semiconductor structure. The semiconductor device includes a first metallization layer on the semiconductor structure. The first metallization layer includes a distributed gate runner network. The distributed gate runner network includes a plurality of non-contacting gate runners. The non-contacting gate runners are separated from one another in the first metallization layer such that there is no conductive electrical connection between the non-contacting gate runners in the first metallization layer.

Another example aspect of the present disclosure is directed to a method of forming a semiconductor device. The method includes forming a first metallization layer on a silicon carbide-based semiconductor structure. The first metallization layer includes one or more metal structures. The method includes forming an insulating layer on the first metallization layer. The insulating layer includes an insulating portion. The insulating portion is patterned to insulate the one or more metal structures of the first metallization layer. The method includes forming a second metallization layer overlapping the first metallization layer.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a power semiconductor device including a single topside metallization layer.

FIG. 2 depicts a power semiconductor device including a single topside metallization layer.

FIG. 3 depicts a power semiconductor device including a single topside metallization layer.

FIG. 4 depicts a power semiconductor device according to example embodiments of the present disclosure.

FIG. 5 depicts a cross-sectional view of the power semiconductor device of FIG. 4.

FIG. 6 depicts a cross-sectional view of the power semiconductor device of FIG. 4.

FIG. 7 depicts a power semiconductor device according to example embodiments of the present disclosure.

FIG. 8 depicts a cross-sectional view of the power semiconductor device of FIG. 7.

FIG. 9 depicts a cross-sectional view of the power semiconductor device of FIG. 7.

FIGS. 10A, 10B, and 10C depict example power semiconductor devices incorporating a sensor according to example embodiments of the present disclosure.

FIGS. 11A, 11B, 11C, 11D, 11E, 11F, 11G, 11H, 11I, 11J, 11K, 11M, 11N, 11O, 11P, 11Q, 11R, 11S, 11T, and 11U depict example bonding layer configurations for power semiconductor devices according to example embodiments of the present disclosure.

FIGS. 12A, 12B, 12C, 12D, 12E, 12F, 12G, 12H, 12I, and 12J depict example gate runner networks for power semiconductor devices according to example embodiments of the present disclosure.

FIG. 13 depicts a power semiconductor device incorporating a distributed gate runner network according to example embodiments of the present disclosure.

FIGS. 14A, 14B, 14C, 14D, and 14E depict example distributed gate runner networks according to example embodiments of the present disclosure.

FIG. 15 depicts a flow chart of an example method according to example embodiments of the present disclosure.

FIG. 16 depicts a flow chart of an example method according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Example aspects of the present disclosure are directed to power semiconductor devices, and more particularly to improved layout of interconnect layers of power semiconductor devices using multiple layer metallization (e.g., multiple metal layers) to improve performance, functionality, and packaging of the power semiconductor devices. Power semiconductor devices, such as power MOSFETs, may have a lateral structure or a vertical structure. A power semiconductor device having a lateral structure has both the source region and the drain region of the power semiconductor device on the same major surface (e.g., upper surface or lower surface) of a semiconductor structure of the device. In contrast, a power semiconductor device having a vertical structure has its source region on one major surface of the semiconductor layer structure and its drain region on the other (opposed) major surface thereof. Vertical device structures are typically used in very high-power applications, as the vertical structure allows for a thick semiconductor drift layer that may support high current densities and block high voltages.

Silicon carbide-based power semiconductor devices offer a high level of performance benefits, including high voltage blocking, low on-resistance, high current, fast switching, low switching losses, high junction temperatures, and high thermal conductivity. Ultimately, these characteristics result in a notable increase in potential power density, which is power conducted per unit area or per unit volume. Achieving increased performance of silicon carbide-based power semiconductor devices may require addressing significant challenges at the device, package, and system level. The higher voltages, currents, and switching speeds manifest into significantly higher electrical, thermal, and mechanical stresses applied onto smaller and more constrained areas as chip sizes are scaled down.

For instance, a vertical silicon carbide-based power semiconductor device may include a silicon carbide drift region that is formed on a silicon carbide substrate, such as a silicon carbide wafer. The device has an active region, as well as one or more inactive regions, such as an edge termination region or a gate bond pad region. The active region acts as a main junction for blocking voltage during reverse bias operation and providing current flow during forward bias operation. The power semiconductor device typically has a unit cell structure, meaning that the active region includes a large number of individual “unit cell” devices (e.g., MOSFETs) that are electrically connected in parallel to function as a single power semiconductor device. In high power applications, such a device may include thousands or tens of thousands of unit cells. It is generally desirable to maximize the total active area of the power semiconductor device, since the total active area is directly proportional to current carrying capacity.

Interconnect layers of a power semiconductor device may be used to facilitate the coupling or connection of the individual “unit cell” devices of the semiconductor structure to external components (e.g., for packaging of the power semiconductor device). The internal layout, or physical arrangement of the various elements in the interconnect layers of a power semiconductor device, may have a prominent influence on the performance and reliability of the power semiconductor device. Components and structures that may need to be implemented into interconnect layers of a power semiconductor device may include, for instance, electrical interconnection structures, electrical isolation structures, heat transfer structures, structures for protection from environmental contamination and moisture, high current power connection interfaces, low current signal power connection interfaces, low current signal distribution networks (e.g., gate runner networks), dielectric coating/masking, topside metallization, backside metallization, edge terminations, lumped signal resistors, current sensors, and/or temperature sensors. Each of these components or structures may compete with the active area for space in the power semiconductor device. It becomes increasingly more difficult to realize an optimal layout as the number of competing structures increases and the overall device area decreases.

As an example, features such as gate runners to reduce signal loop impedance and bonding pads for signal interconnection compete for the same real estate as the active area where the switching cells are formed. Accordingly, there is a tradeoff, for instance, between switching quality (speed, loss, and overshoot) and the on-state resistance of the power loop.

Some power semiconductor devices include a single topside metallization layer as part of the interconnect layer structure of the power semiconductor device. The single topside metallization layer may form an electrical connection to the various electrical connection sites across the structure. This topside metallization layer may be part of a interconnect layer stack with various layers used to form ohmic contacts, adhesion, diffusion barriers, and metallurgical compatibility with the attach method used for the topside pads (wire bonding, soldering, sintering, etc.). A backside metallization layer may also be applied as part of the fundamental structure, including an ohmic contact and a metal stack compatible with the desired device attach material and process (soldering, sintering, etc.).

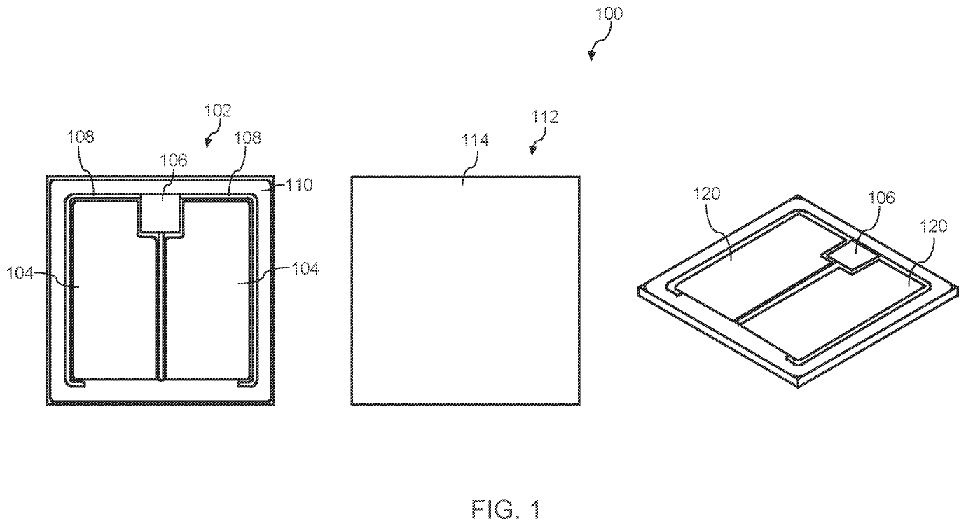

For instance, FIG. 1 depicts example interconnect layers of a power semiconductor device 100 that includes topside metallization directly on a semiconductor layer. More particularly, the power semiconductor device 100 may include a metallization layer 102. The metallization layer 102 may be directly on a semiconductor structure 104 with semiconductor unit cell devices (e.g., silicon carbide-based MOSFETs, diodes, transistors, or other semiconductor unit cell devices). The semiconductor structure 104 includes an active region that acts, for instance, as a main junction for blocking voltage during reverse bias operation and providing current flow during forward bias operation. The metallization layer 102 may include metal structures including a gate pad 106, gate runners 108, and may also include an edge termination structure 110. The gate pad 106 may be large in comparison to the size of the power semiconductor device 100. The plurality of gate runners 108 (e.g., gate buses) may extend from the gate pad 106 to better distribute a gate signal to the outer edges and to the middle of the power semiconductor device 100. The edge termination structure 110 may be around the perimeter of the power semiconductor device 100 to buffer an electric field so that voltage over distance is reduced. The space occupied by the gate pad 106, gate runners 108 and edge termination structure 110 may reduce the active area available of the semiconductor structure 104. As shown in FIG. 1, a backside metallization layer 112 including a drain attach pad 114 may be on the backside of the semiconductor structure 104 to form a vertical structure power semiconductor device 100.

The metallization layer 102 may include metallized pads (e.g. the gate bonding pad 106 and source bonding pads 120) for power and signal connection to other components (e.g., substrates, lead frames, terminals, etc.) so that the metallization layer 102 acts as a bonding layer for the power semiconductor device 100. b. Signal connections to the gate bonding pad 118 may be implemented, for instance, using wire bond(s). The source bonding pads 120 may be directly on the active region of the semiconductor structure 104. A power connection may be made to the source bonding pads 120 using a clip or similar attach which is directly soldered, sintered, welded to the source bonding pads 120. The source bonding pads 120 may serve as source contact(s) or other contacts (e.g., ohmic contacts, Schottky contacts, etc.) for the semiconductor unit cells in the active region(s) of the semiconductor structure 104 of the power semiconductor device 100.

As illustrated in FIG. 1, the gate pad 106, gate runners 108, and edge termination structure 110 may be features of the semiconductor power device 100 but are not considered “active area” which contributes to the ability to conduct current. As illustrated, these features may typically take up a significant percentage of the total device area. The space these regions take up, particularly the gate pad 106 and the edge termination structure 110, may be considered a fixed value such that the percentage of chip area these structures occupy increases as the chip size decreases. In some cases, the area used for these features may be reduced as much as possible to achieve the lowest possible on-resistance of the power-semiconductor device.

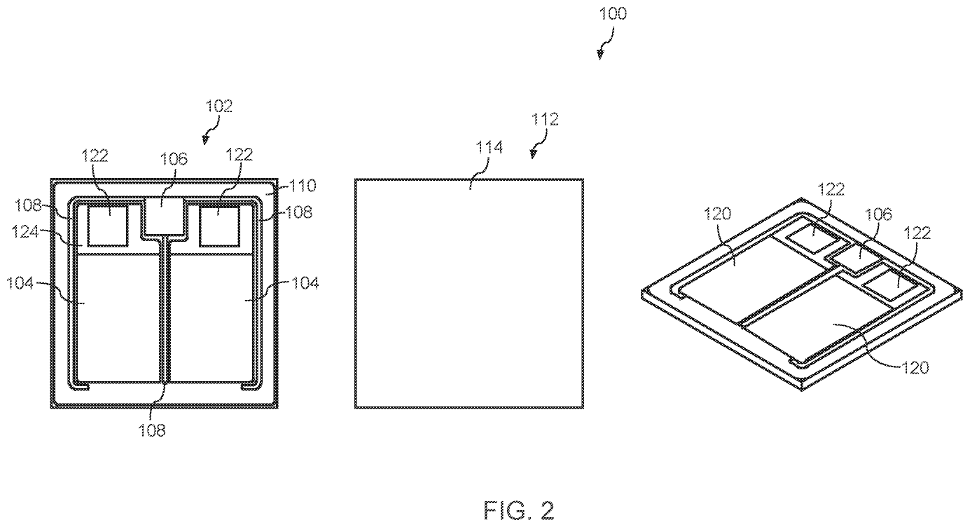

Referring to FIG. 2, in some examples, the power semiconductor device 100 may include source kelvin bond pad(s) 122 to further decouple the power loops and signal loops. To keep attach material associated with the source kelvin bond pad(s) 122 off of the gate bonding pad 106, which may interfere with the wire bonding process, the source kelvin bond pad(s) 122 may be masked off with a dielectric barrier 124 or similar barrier material to keep the source kelvin bond pad(s) 122 pristine. The source kelvin bond pad(s) 122 further reduces the active area of the semiconductor structure 104 of the power semiconductor device 100. However, there is active area under the dielectric barrier 124 used to mask off the source kelvin bond pad(s) 122.

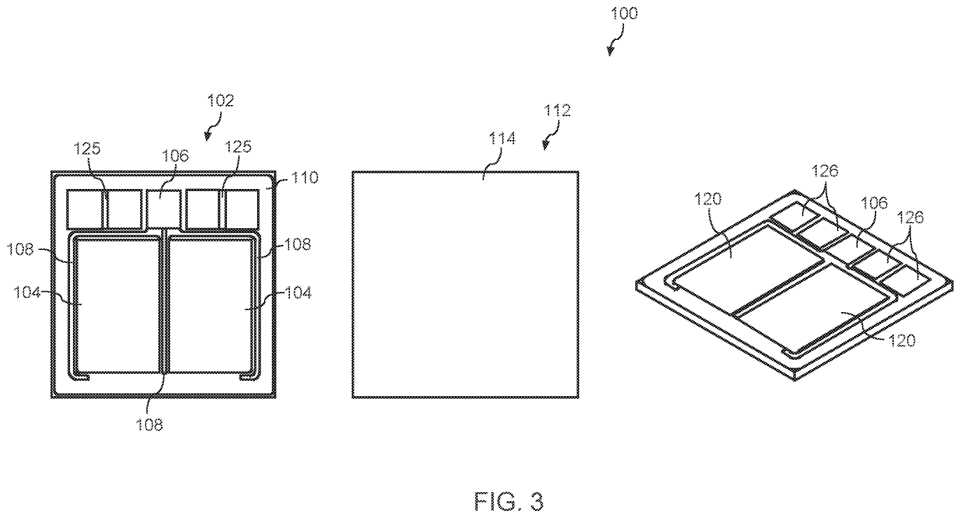

The amount of active area available for a given chip size becomes even more constrained in the event that on-chip sensors or other ancillary features are used. In these examples, space is not only needed for the feature itself, but also for the bonding pads to provide electrical interconnection to the feature. For instance, FIG. 3 illustrates an example power semiconductor device 100 with two sensors 125. Each sensor 125 takes up active area for the sensing element itself and independent isolated sensor bonding pads 126. As demonstrated by FIGS. 1-3, when limited to a single metallization layer as an interconnect layer on the semiconductor structure 104, straightforward as well as more integrated structures may suffer from the available chip area required to accommodate practical packaging features as well as ancillary but effective additional features.

Example aspects of the present disclosure are directed to power semiconductor devices that have multiple interconnect layers of metallization and/or additional layers in the topside interconnect layer scheme to increase the size of the active area of the semiconductor structure of the power semiconductor device while achieving packaging, interconnection, and/or other functions (sensing) using structures on the additional interconnect layers. In some embodiments, a power semiconductor device may include a semiconductor structure including an active area. The active area may include a plurality of unit cell devices, such as silicon carbide-based MOSFETs, located between a source contact and a drain contact to form, for instance, a vertical structure power semiconductor device. Aspects of the present disclosure are discussed with reference to silicon carbide-based MOSFET unit cell devices for purposes of illustration and discussion. Those of ordinary skill in the art, using the disclosures provided herein, will understand that the unit cell devices may be other semiconductor devices without deviating from the scope of the present disclosure, such as diodes (e.g. Schottky diodes), transistors, or other devices.

The interconnect layers of the power semiconductor device may include a first metallization layer directly on the silicon carbide-based semiconductor structure. The first metallization layer may include one or more metal structures, such as gate runners, vias, interconnect structures, sensors, connections to underlying sensors, etc. The interconnect layers of the power semiconductor device may include a second metallization layer at least partially overlapping the first metallization layer. As used herein, a first structure “at least overlaps” a second structure if an axis that is perpendicular to a major surface of the first structure passes through both the first structure and the second structure. The second metallization layer may form a bonding layer for the power semiconductor device and may include bonding pads for power connections, signal connections, sensor connections, etc.

The interconnect scheme of the power semiconductor device may include an insulating layer between the first metallization layer and the second metallization layer. The insulating layer may include an insulating portion. The insulating portion may be a dielectric material. The insulating portion may be patterned to insulate the one or more metal structures of the first metallization layer. In this way, the power semiconductor device may accommodate the second metallization layer including, for instance, the one or more bond pads, without interfering or creating undesirable electrical connections with the metal structures associated with the first metallization layer. In some embodiments, the insulating layer may include one or more source contact openings patterned into the insulating portion. The source contact openings may accommodate source contacts extending from, for instance, the second metallization layer to the active regions of the semiconductor structure of the power semiconductor device.

In some embodiments, the interconnect layers of the power semiconductor device may include a third metallization layer directly on the insulating layer. The third metallization layer may include one or more metal structures (e.g., vias, planar interconnect structures, sensors, etc.). The third metallization layer may facilitate conductive electrical connection of metal structures in the first metallization layer and the second metallization layer.

In some embodiments, the interconnect layers of the power semiconductor device may include a second insulating layer between the third metallization layer and the second metallization layer. The second insulating layer may include an insulating portion that is patterned to insulate one or more metal structures of the first metallization layer and/or the interconnection layer. In some embodiments, the second insulating layer may include one or more source contact openings patterned into the insulating portion. The source contact openings may accommodate source contacts extending from, for instance, the second metallization layer to the active regions of semiconductor structure of the power semiconductor device.

Aspects of the present disclosure provide technical effects and benefits. For instance, aspects of the present disclosure provide for the implementation of multiple topside metal layers on a power semiconductor device such that performance may be improved, functionality may be added, and packaging may be made easier. Limited to a single metallization and isolation layer, the topside metal pattern must match or be removed from the underlying structure and locations of the functional elements, including active switching cells, signal runners, gate bonding pads, edge terminations, and ancillary features such as on-chip current and temperature sensors.

For instance, a power semiconductor device having multiple layers of topside metallization according to example embodiments of the present disclosure may provide increased flexibility in how gate runner networks are incorporated into the power semiconductor device. Gate runners may be used to reduce the distributed impedance of the control switching loop. Gate runners may be considered high speed “highways” of high electrical conductivity until the gate signal is distributed to the individual power semiconductor cells. Gate runners may be distributed around the outer edge regions and through the middle of the device such that the furthest cells from the gate (or similar) pad do not turn on appreciably slower than the ones closest to it.

In power semiconductor devices having a single topside metallization layer, gate runners may have to be carefully balanced with their position and pattern with respect to the gate pad. As an example, an edge gate bonding pad would normally have a long relative path to the furthest sides of the power semiconductor device, so the cells on the opposite edge region would need many gate runners to reduce the relative impedance. The gate runners themselves take up space which may otherwise be used for more active area and accordingly lower on-resistances. Multiple topside metallization layers on the power semiconductor device may allow for robust, well distributed gate runners directly on the active layer itself or on an additional metallization layer(s) in the stack.

With additional layers of insulators and conductors, more complicated routing may occur. This acts to “decouple” the ideal chip layout for device performance from the ideal chip layout for packaging. With multiple layers, the area used for gate distribution and interconnection may be reduced on a first metallization layer, and then large, bondable regions may be formed on an upper metallization layer. Additional features such as sensors, signal resistors, etc. may be formed in the inner or upper layer without sacrificing active area on the semiconductor structure of the power semiconductor device.

Embodiments of the present disclosure may vary significantly based on the specific applications for and intended usage of the power semiconductor devices. In some examples, the use of multiple metallization layers in the power semiconductor structure may be used to achieve one or more of the goals for the power semiconductor devices depending on application specific requirements, including high power density (e.g., small package size), high current carrying capability, high voltage capability, high temperature operation, low thermal resistance, low stray inductance, fast switching with reduced losses, high efficiency through low on-resistance, high efficiency through high speed switching with reduced losses, thoughtful external terminal layout for effective interconnection, compliance with creepage and clearance standards, Moisture Sensitivity Level (MSL) compliance, lower cost, and other goals.

Aspects of the present disclosure are discussed with reference to silicon carbide-based semiconductor structures. Those of ordinary skill in the art, using the disclosures provided herein, will understand that the power semiconductor devices according to example embodiments of the present disclosure may be used with any semiconductor material, such as other wide band gap semiconductor materials. without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

With reference now to the Figures, example embodiments of the present disclosure will now be set forth.

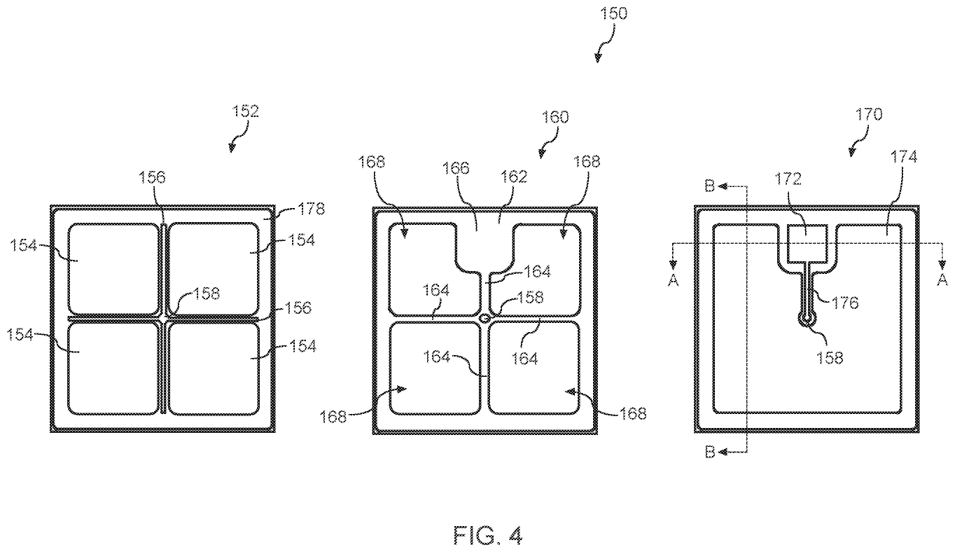

FIG. 4 depicts example interconnect layers of a power semiconductor device 150 according to example embodiments of the present disclosure. More particularly, the power semiconductor device 150 may include a first metallization layer 152. The first metallization layer 152 may be directly on the semiconductor structure 154 with active regions including semiconductor unit cells (e.g., silicon carbide-based MOSFETs or other devices). The first metallization layer 152 may include metal structures, including gate runners 156 and a gate via 158. As used herein, the metal structures directly on the semiconductor structure 154 for metallization, interconnection, gate distribution, etc. form the first metallization layer 152.

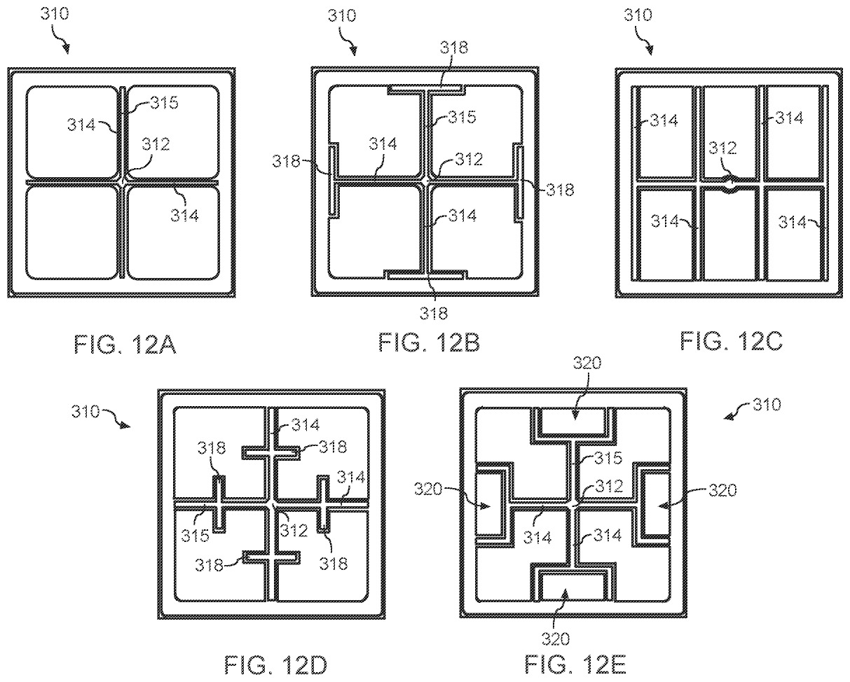

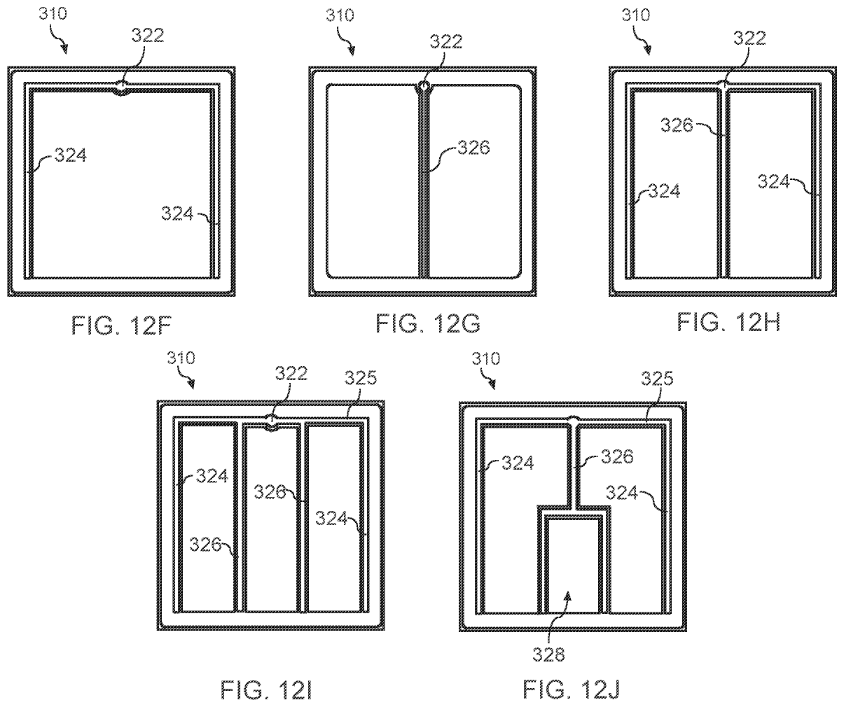

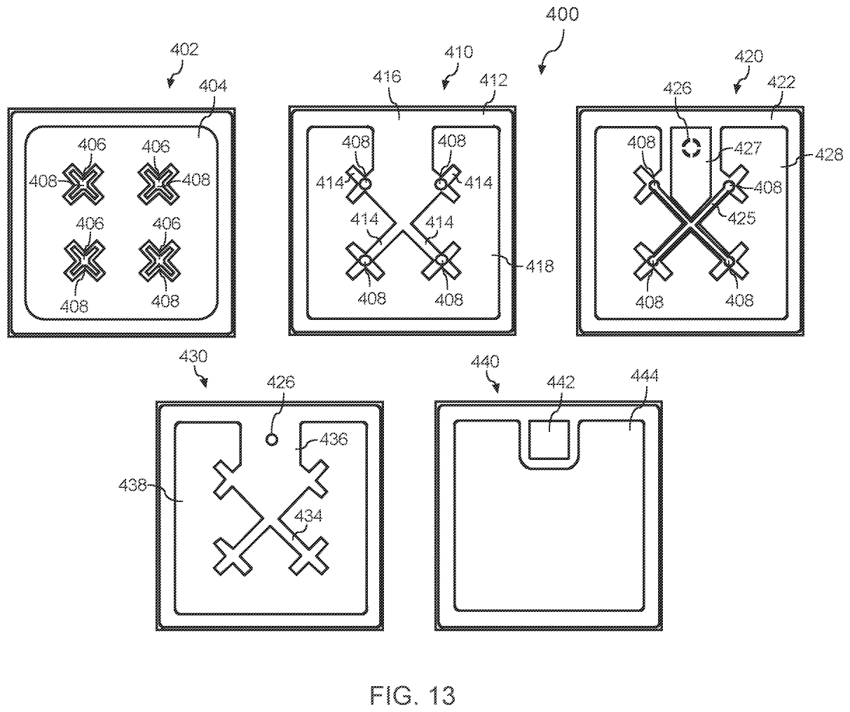

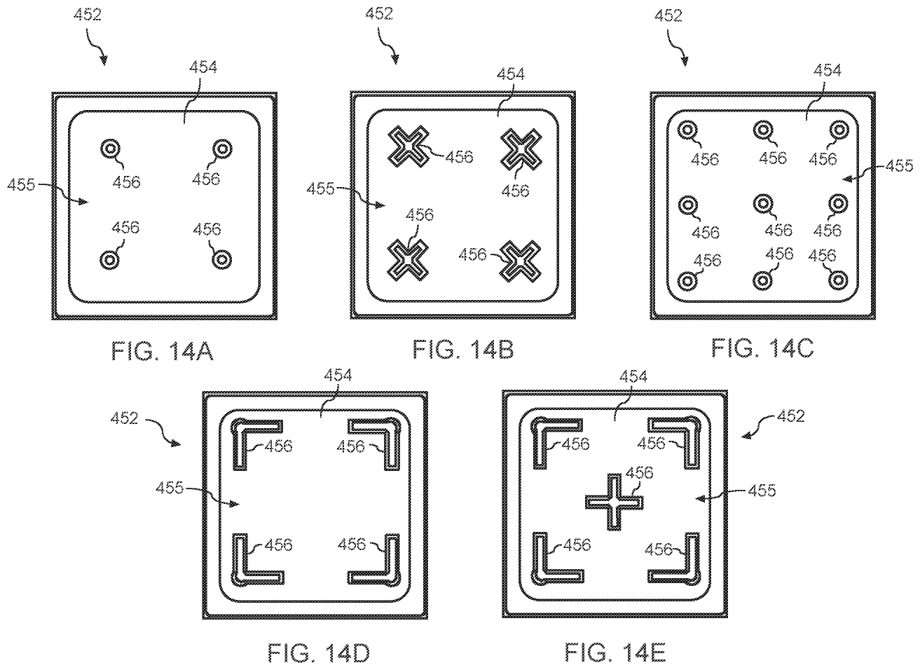

The plurality of gate runners 156 (e.g., gate buses) are used to distribute a gate signal through the power semiconductor device 150. The plurality of gate runners 156 of FIG. 4 form a gate runner network. The gate runner network of FIG. 4 is a crosshairs gate runner network. More particularly, two gate runners may intersect one another in a central portion of the first metallization layer 152 and may be about perpendicular to one another. In addition, the two gate runners may have about the same length or may have differing lengths. Other suitable gate runner configurations/networks may be used without deviating from the scope of the present disclosure. Example gate runner configurations are illustrated in FIGS. 12A-12J, FIG. 13, and in FIGS. 14A-14E.

In some embodiments, the gate runners 156 may take up a small amount of the area of the first metallization layer 152, increasing the availability of area for the active regions of the semiconductor structure 154. In some embodiments, the gate runners 156 may take up about 10% or less of the area of the first metallization layer 152, such as about 5% or less, such as about 3% or less, such as about 1% or less, such as about 0.5% or less. A gate via 158 may be used to communicate signals to the gate runners 156. The gate via 158 may extend through a central portion of the power semiconductor device 150. However, other suitable configurations and/or locations of gate vias may be used as illustrated in FIGS. 14A-14E.

An insulating layer 160 may be on the first metallization layer 152. The insulating layer 160 may include an insulating portion 162. The insulating portion 162 may be a dielectric material (e.g., a dielectric coating). The insulating portion 162 may be patterned to insulate or to mask the one or more metal structures of the first topside metallization layer. More particularly, the insulating portion 162 may be patterned to cover certain structures in the first metallization layer 152 while leaving other features (e.g., portions of active regions of the semiconductor structure 154) uncovered.

For instance, the insulating portion 162 may include masking portions 164 operable to insulate or to mask the gate runners 156 of the first metallization layer 152. The insulating portion 162 may be patterned to form source contact openings 168. The source contact openings 168 may accommodate source contacts extending from, for instance, a source bond pad 174 on a second metallization layer 170 (e.g., a bonding layer). The insulating portion 162 may include a gate pad portion 166. The gate via 158 may extend through the insulating portion 162 of the insulating layer 160.

The second metallization layer 170 may be on the insulating layer 160 such that the insulating layer 160 is between the first metallization layer 152 and the second metallization layer 170. In some embodiments, the second metallization layer 170 may act as a bonding layer for the power semiconductor device 150. In the example of FIG. 4, the second metallization layer 170 includes a large gate bonding pad 172 at a center edge region of the power semiconductor device 150, which may be a useful location for packaging. The second metallization layer 170 may include a planar interconnect structure 176 that conductively electrically connects the gate bonding pad 172 with the gate via 158 and thus to the gate runners 156 of the power semiconductor device 150. The second metallization layer 170 may include a large source bonding pad 174. Source contact(s) may extend from the source bonding pad 174 through the source contact openings 168 of the insulating layer 160 to the active regions of the semiconductor structure 154 of the power semiconductor device 100.

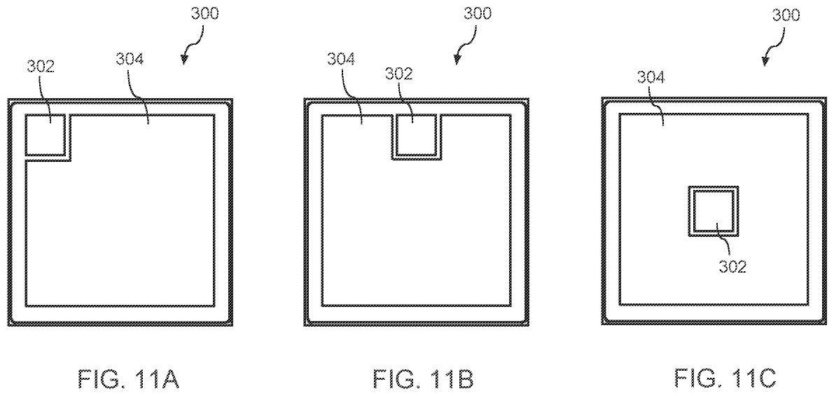

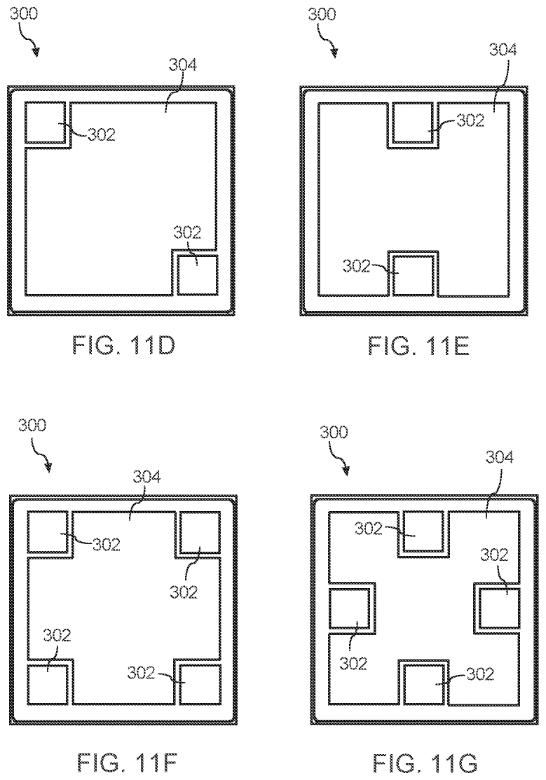

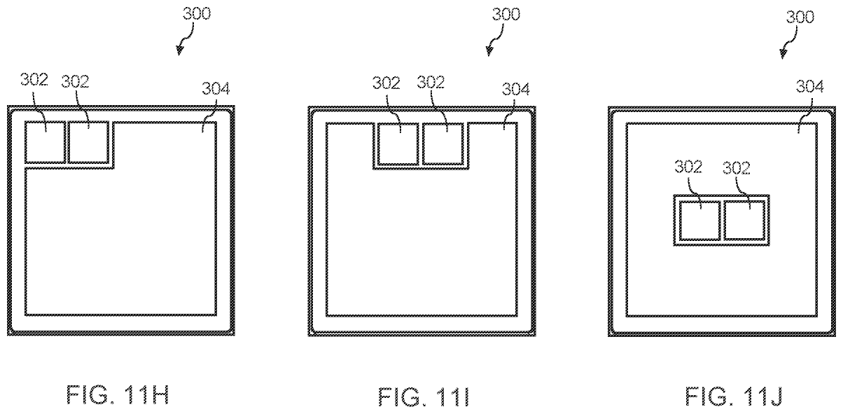

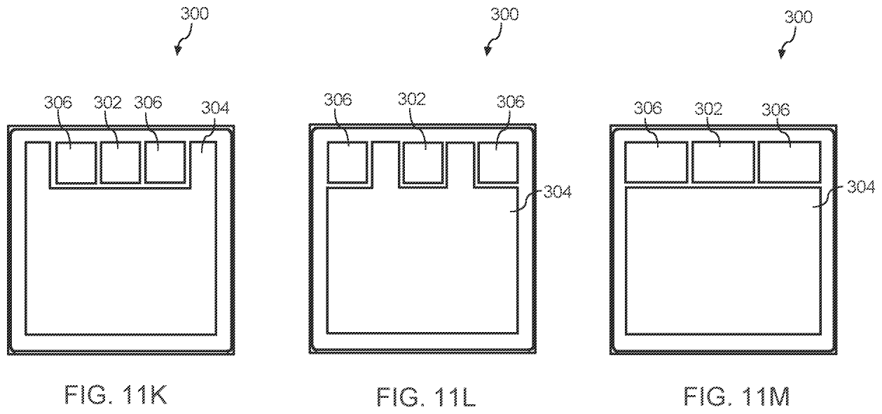

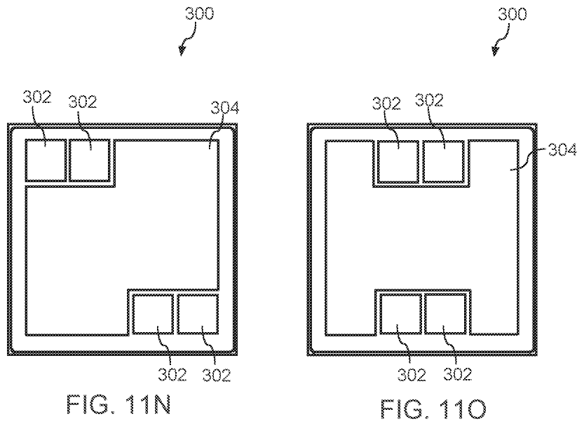

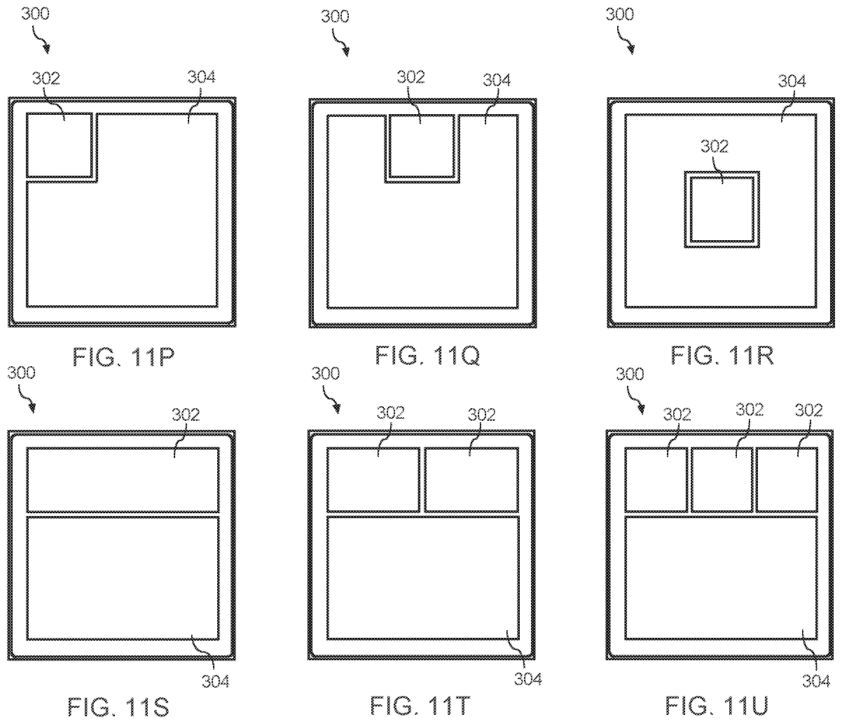

The second metallization layer 170 may be used for interconnection of the power semiconductor device 150 to elements of a semiconductor package, including substrates, lead frames, terminals, etc. Interconnection methods may vary based on package type, but may include wire bonding, soldering, sintering, conductive epoxy, or similar electrically conductive material. Other suitable configurations of the gate bonding pad 172 and the source bonding pad 174 may be used without deviating from the scope of the present disclosure. Example bonding layer configurations are illustrated in FIGS. 11A-11U.

The power semiconductor device 150 may include other structures without deviating from the scope of the present disclosure. For instance, the power semiconductor device 150 may include a backside metallization layer (not shown) including a drain attach pad on the backside of the semiconductor structure 154 to form a vertical structure power semiconductor device 150. The power semiconductor device 150 may include an insulating layer (not shown) on the second metallization layer. The power semiconductor device 150 may include an edge termination structure 178.

FIG. 5 depicts a cross-sectional view of the power semiconductor device 150 of FIG. 4 taken along line A-A′. FIG. 5 is intended to represent structures for identification and description and is not intended to represent the structures to physical scale. As shown, the power semiconductor device 150 includes a first metallization layer 152 directly on a semiconductor structure 154. The power semiconductor device 150 includes an insulating layer 160. The power semiconductor device 150 includes a second metallization layer 170 (e.g., a bonding layer). The layer boundaries are illustrated in dashed line for purposes of illustration. Those of ordinary skill in the art, using the disclosures provided herein, will understand that the layers of the power semiconductor device 150 may all be assembled together to form a composite structure that may or may not include discrete layer boundaries in the final assembled power semiconductor device 150.

As shown in FIG. 5, the power semiconductor device 150 includes the gate bonding pad 172 and the source bonding pad 174 in the second metallization layer 170. The insulating portion of the insulating layer 160 includes a gate pad portion 166. The first metallization layer 152 includes the gate runner 156. An insulating portion 157 may separate the gate runner 156 from other metal (e.g., source contact) in the first metallization layer 152. The insulating layer 160 includes source contact openings to accommodate the source contact extending from the source bonding pad 174 to the active region of the semiconductor structure 154

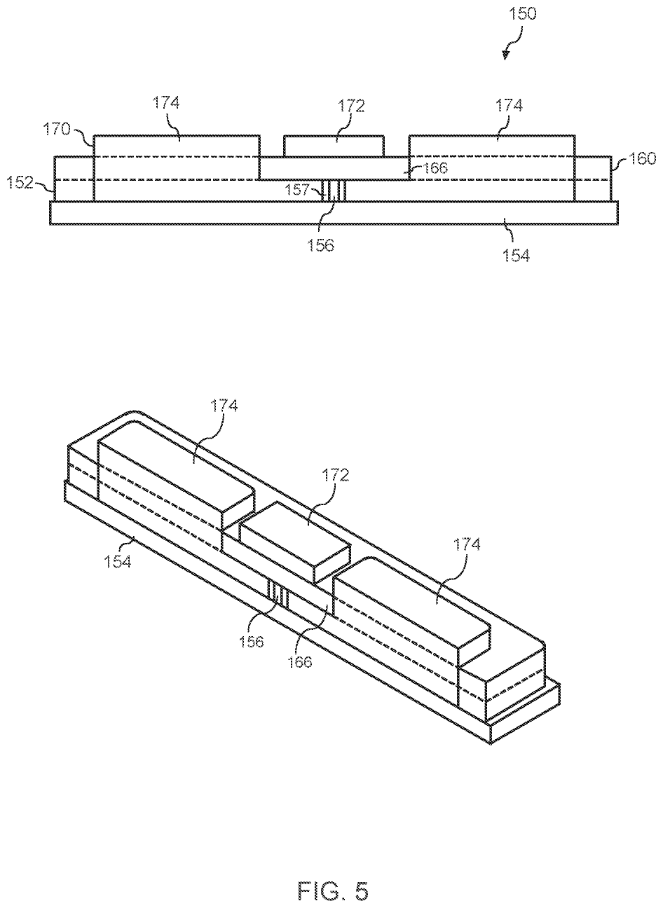

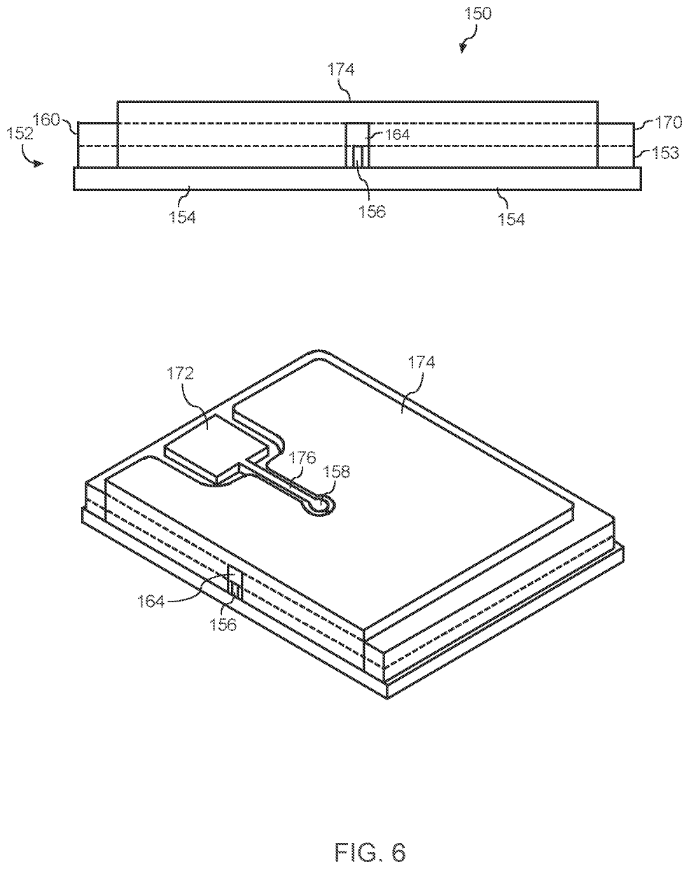

FIG. 6 depicts a cross-sectional view of the power semiconductor device 150 of FIG. 4 taken along line B-B′. FIG. 6 is intended to represent structures for identification and description and is not intended to represent the structures to physical scale. As shown, the power semiconductor device 150 includes a first metallization layer 152 directly on the semiconductor structure 154. The power semiconductor device 150 includes an insulating layer 160. The power semiconductor device 150 includes a second metallization layer 170 (e.g., a bonding layer). The layer boundaries are illustrated in dashed line for purposes of illustration. Those of ordinary skill in the art, using the disclosures provided herein, will understand that the layers of the power semiconductor device 150 may all be assembled together to form a composite structure that may or may not include discrete layer boundaries in the final assembled power semiconductor device 150.

As shown in FIG. 6, the power semiconductor device 150 includes the gate bonding pad 172 and the source bonding pad 174 in the second metallization layer 170. The insulating portion of the insulating layer 160 includes a masking portion 164 to insulate or to mask the gate runner 156 in the first metallization layer 152. An insulating portion 157 may separate the gate runner 156 from other metal (e.g., source contact) in the first metallization layer 153. The insulating layer 160 includes source contact openings to accommodate the source contact extending from the source bonding pad 174 to the active region of the semiconductor structure 154.

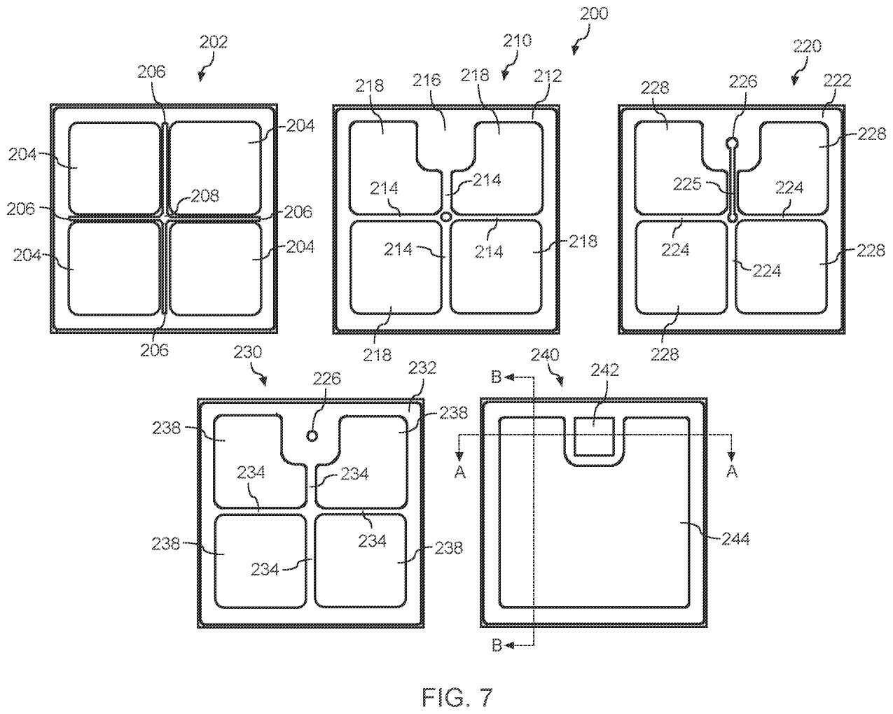

FIG. 7 depicts example interconnect layers of a power semiconductor device 200 incorporating a third metallization layer according to example embodiments of the present disclosure. More particularly, the power semiconductor device 200 may include a first metallization layer 202. The first metallization layer 202 may be directly on a semiconductor structure 204 with active regions including semiconductor unit cells (e.g., silicon carbide-based MOSFETs or other devices). The first metallization layer 202 may include metal structures, including gate runners 206 and a gate via 208. As used herein, the metal structures directly on the semiconductor structure 204 for metallization, interconnection, gate distribution, etc. form the metallization layer 202.

The plurality of gate runners 206 (e.g., gate buses) are used to distribute a gate signal through the power semiconductor device 200. The plurality of gate runners 206 of FIG. 7 form a gate runner network. The gate runner network of FIG. 7 is a crosshairs gate runner network. In a crosshairs gate runner network, two gate runners may intersect one another in a central portion of the first metallization layer 202 and may be about perpendicular to one another. In addition, the two gate runners 206 may have about the same length or may have differing lengths. Other suitable gate runner configurations/networks may be used without deviating from the scope of the present disclosure. Example gate runner configurations are illustrated in FIGS. 12A-12J, FIG. 13, and in FIGS. 14A-14E.

In some embodiments, the gate runners 206 may take up a small amount of the area of the first metallization layer 202, increasing the availability of area for the active regions of the semiconductor structure 204. In some embodiments, the gate runners 206 may take up about 10% or less of the area of the first metallization layer 202, such as about 5% or less, such as about 3% or less, such as about 1% or less, such as about 0.5% or less. A gate via 208 may be used to communicate signals to the gate runners 206. The gate via 208 may extend through a central portion of the power semiconductor device 200.

A first insulating layer 210 may be on the first metallization layer 202 (e.g., on the first metallization layer). The first insulating layer 210 may include an insulating portion 212. The insulating portion 212 may be a dielectric material (e.g., a dielectric coating). The insulating portion 212 may be patterned to insulate the one or more metal structures of the first metallization layer. More particularly, the insulating portion 212 may be patterned to cover certain metal structures in the first metallization layer 202 while leaving other features (e.g., portions of active regions of the semiconductor structure 204) uncovered.

For instance, the insulating portion 212 may include masking portions 214 operable to insulate or to mask the gate runners 206 of the first metallization layer 202. The insulating portion 212 may be patterned to form source contact openings 218. The source contact openings 218 may accommodate source contacts extending from, for instance, a source bond pad 244 on a second metallization layer 240 (e.g., a bonding layer). The insulating portion 212 may include a gate pad portion 216. The gate via 208 may extend through the insulating portion 212 of the insulating layer 210.

In the example of FIG. 7, the power semiconductor device 200 may include a third metallization layer 220. The third metallization layer 220 may include an insulating portion 222. The insulating portion 222 may be a dielectric material (e.g., dielectric coating). The insulating portion 222 may be patterned in a similar manner as the insulating portion 212 of the first insulating layer 210. For instance, the insulating portion 222 may include masking portions 224 to insulate or to mask the gate runners 206. The insulating portion 222 may include source contact openings 228. The source contact openings 228 may accommodate source contacts extending from, for instance, a source bond pad 244 in the second metallization layer 240 (e.g., a bonding layer).

The third metallization layer 220 may include one or more metal structures. The metal structures may be used, for instance, to route power and/or signal vias to more desirable locations withing the power semiconductor device 200. In the example of FIG. 7, the third metallization layer 220 includes a planar interconnect structure 225 used to route the gate via 208 to a second gate via 226.

The power semiconductor device 200 may include a second insulating layer 230. The second insulating layer 230 may be on the third metallization layer 220. Similar to the insulating layer 210, the second insulating layer 230 may include an insulating portion 232. The insulating portion 232 may be a dielectric material (e.g., a dielectric coating). The insulating portion 232 may be patterned in a similar manner as the insulating portion 212 of the first insulating layer 210. For instance, the insulating portion 232 may include masking portions 234 to insulate or to mask the gate runners 206. The insulating portion 232 may include source contact openings 238. The source contact openings 228 may accommodate source contacts extending from, for instance, a source bond pad 244 in the second metallization layer 240 (e.g., a bonding layer).

The second metallization layer 240 may be on the second insulating layer 230 such that the second insulating layer 230 is between the third metallization layer 220 and the second metallization layer 240. In some embodiments, the second metallization layer 240 may act as a bonding layer for the power semiconductor device 200. In the example of FIG. 7, the second metallization layer 240 includes a large gate bonding pad 242 at a center edge region of the power semiconductor device 200, which may be a useful location for packaging. The second metallization layer 240 may include a large source bonding pad 244. Other suitable configurations of the gate bonding pad 242 and the source bonding pad 244 may be used without deviating from the scope of the present disclosure. Example bonding layer configurations are illustrated in FIGS. 11A-11U.

The second metallization layer 240 may be used for interconnection of the power semiconductor device 200 to elements of a semiconductor package, including substrates, lead frames, terminals, etc. Interconnection methods may vary based on package type, but may include wire bonding, soldering, sintering, conductive epoxy, or similar electrically conductive material.

The power semiconductor device 200 may include other structures without deviating from the scope of the present disclosure. For instance, the power semiconductor device 200 may include a backside metallization layer (not shown) including a drain attach pad on the backside of the semiconductor structure 204 to form a vertical structure power semiconductor device 200. The power semiconductor device 200 may include an insulating layer (not shown) on the second metallization layer 240. The power semiconductor device 200 may include an edge termination structure.

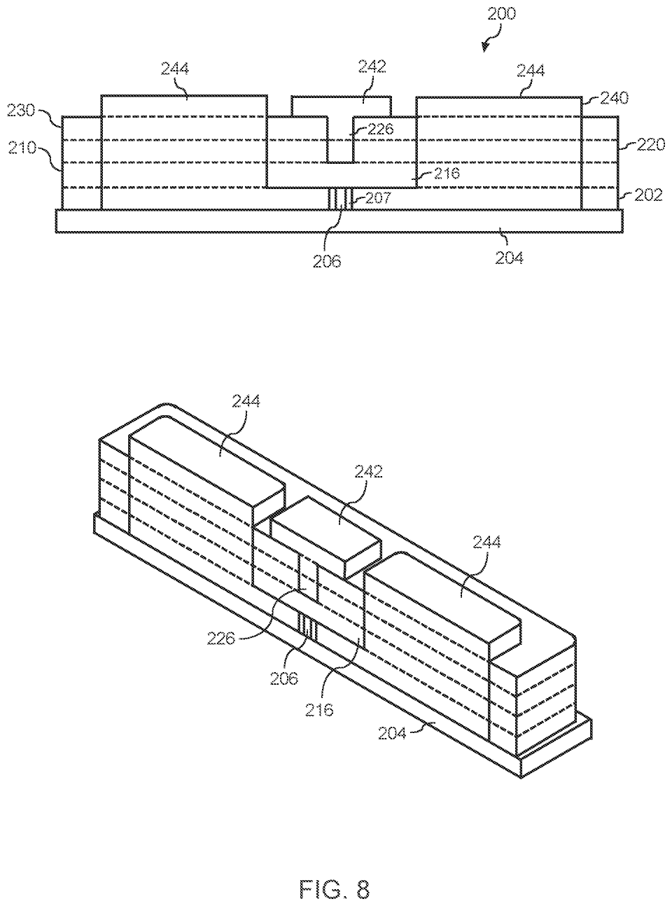

FIG. 8 depicts a cross-sectional view of the power semiconductor device 200 of FIG. 7 taken along line A-A′. FIG. 8 is intended to represent structures for identification and description and is not intended to represent the structures to physical scale. As shown, the power semiconductor device 200 includes a first metallization layer 202 directly on a semiconductor structure 204. The power semiconductor device 200 further includes a first insulating layer 210, a third metallization layer 220, a second insulating layer 220, and a second metallization layer 240 (e.g., a bonding layer). The layer boundaries are illustrated in dashed line for purposes of illustration. Those of ordinary skill in the art, using the disclosures provided herein, will understand that the layers of the power semiconductor device 200 may all be assembled together to form a composite structure that may or may not include discrete layer boundaries in the final assembled power semiconductor device 200.

As shown in FIG. 8, the power semiconductor device 200 includes the gate bonding pad 242 and the source bonding pad 244 in the second metallization layer 240. The insulating portion of the insulating layer 210 includes a gate pad portion 216. The first metallization layer 202 includes the gate runner 206. An insulating portion 207 may separate the gate runner 206 from other metal (e.g., source contact) in the first metallization layer 202. The insulating layer 210 includes source contact openings to accommodate the source contact extending from the source bonding pad 244 to the active region on the semiconductor structure 204.

The third metallization layer 220 may be on the first insulating layer 210. The third metallization layer 220 may include a via 226 extending through the insulating portion 222 in the third metallization layer 220. The third metallization layer 220 includes source contact openings to accommodate the source contact extending from the source bonding pad 244.

The second insulating layer 230 is on the third metallization layer 220. The via 226 extends through insulating portion 232 in the second insulating layer 230. The second insulating layer 230 includes source contact openings to accommodate the source contact extending from the source bonding pad 244.

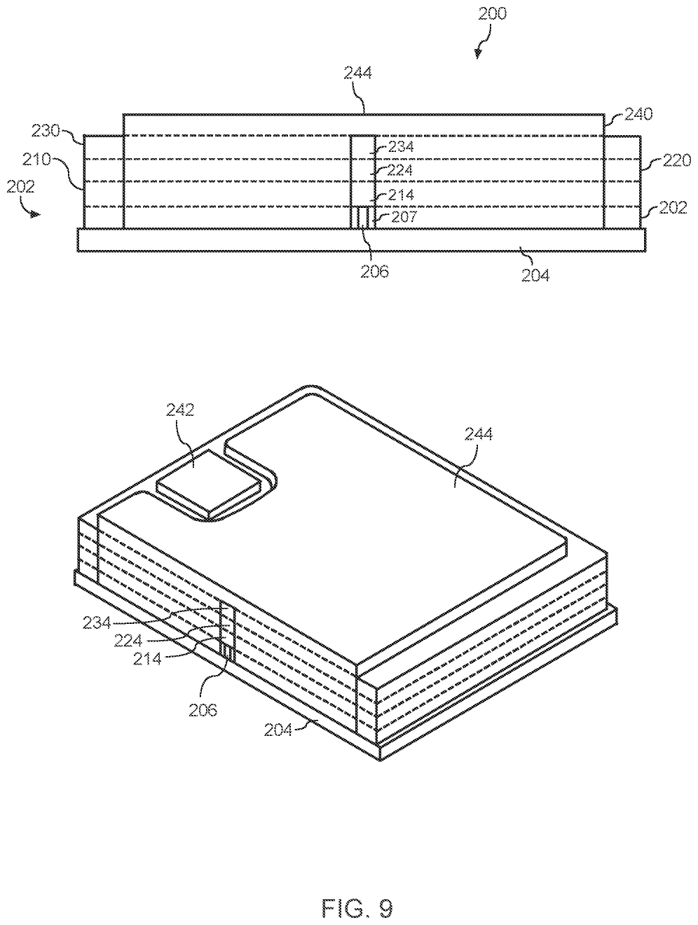

FIG. 9 depicts a cross-sectional view of the power semiconductor device 200 of FIG. 7 taken along line B-B′. FIG. 9 is intended to represent structures for identification and description and is not intended to represent the structures to physical scale. As shown, the power semiconductor device 200 includes a first metallization layer 202 directly on a semiconductor structure 204. The power semiconductor device 200 further includes a first insulating layer 210, a third metallization layer 220, a second insulating layer 220, and a second metallization layer 240 (e.g., a bonding layer). third metallization layer The layer boundaries are illustrated in dashed line for purposes of illustration. Those of ordinary skill in the art, using the disclosures provided herein, will understand that the layers of the power semiconductor device 200 may all be assembled together to form a composite structure that may or may not include discrete layer boundaries in the final assembled power semiconductor device 200.

As shown in FIG. 9, the power semiconductor device 200 includes the gate bonding pad 242 and the source bonding pad 244 in the second metallization layer 240. The insulating portion 212 of the first insulating layer 210 includes a masking portion 214 to insulate or to mask the gate runner 206 in the first metallization layer 202. The first insulating layer 210 includes source contact openings to accommodate the source contact extending from the source bonding pad 244 to the active region of the semiconductor structure 204.

The third metallization layer 220 may be on the first insulating layer 210. The insulating portion 222 of the third metallization layer 220 includes a masking portion 224 to insulate or to mask the gate runner 206 in the first metallization layer 202. The third metallization layer 220 includes source contact openings to accommodate the source contact extending from the source bonding pad 244.

The second insulating layer 230 is on the third metallization layer 220. The insulating portion 232 of the second insulating layer 230 includes a masking portion 234 to insulate or to mask the gate runner 206 in the first metallization layer 202. The second insulating layer 230 includes source contact openings to accommodate the source contact extending from the source bonding pad 244.

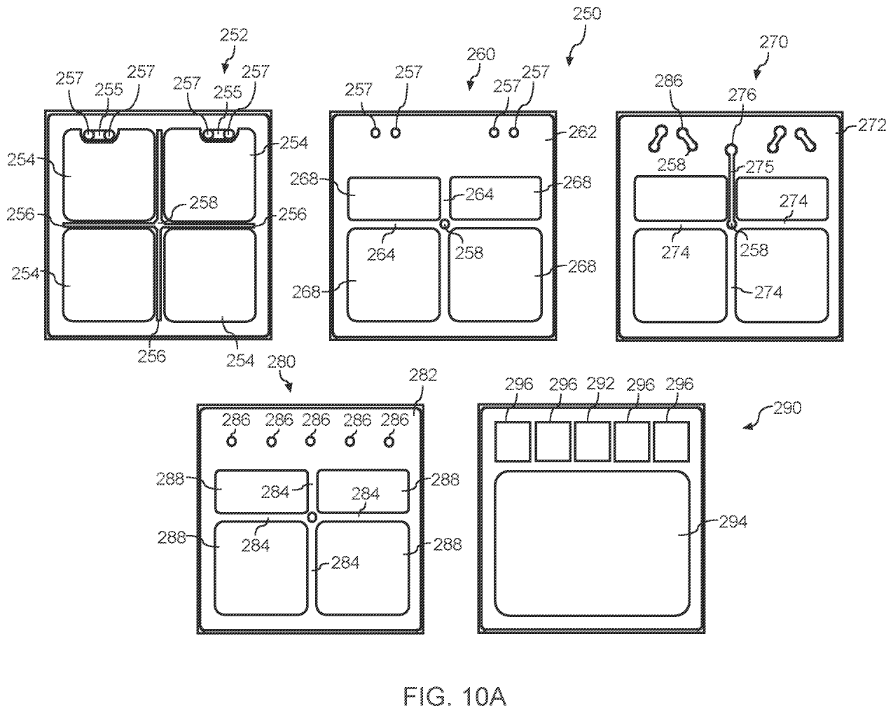

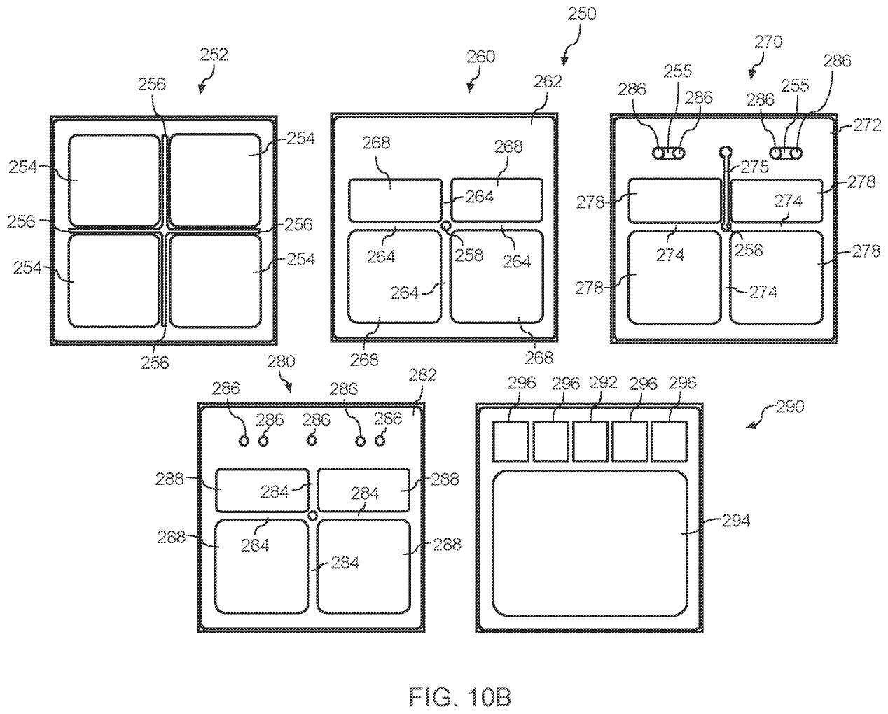

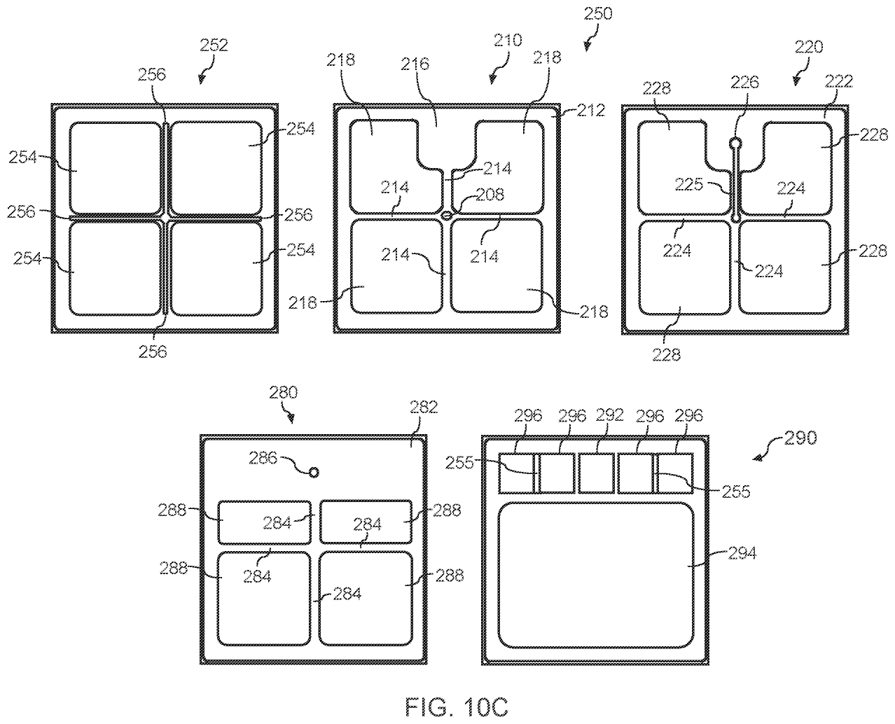

FIGS. 10A-10C depict interconnect layers of example power semiconductor devices 250 with different configurations for integrated on-chip sensor(s) 255 in the power semiconductor devices 250 according to example embodiments of the present disclosure. More particularly, the power semiconductor device 250 of FIG. 10A may include a first metallization layer 252. The first metallization layer 252 may be directly on a semiconductor structure 254 with active regions including semiconductor unit cells (e.g., silicon carbide-based MOSFETs or other devices). The first metallization layer 252 may include metal structures, including gate runners 256 and a gate via 258. As used herein, the metal structures directly on the semiconductor structure 254 for metallization, interconnection, gate distribution, edge termination, etc. form the first metallization layer 252.

The plurality of gate runners 256 (e.g., gate buses) are used to distribute a gate signal through the power semiconductor device 250. The plurality of gate runners 256 of FIG. 10A form a gate runner network. The gate runner network of FIG. 10A is a crosshairs gate runner network. In a crosshairs gate runner network, two gate runners may intersect one another in a central portion of the first metallization layer 252 and may be about perpendicular to one another. In addition, the two gate runners 256 may have about the same length or may have differing lengths. Other suitable gate runner configurations/networks may be used without deviating from the scope of the present disclosure. Example gate runner configurations are illustrated in FIGS. 12A-12J, FIG. 13, and in FIGS. 14A-14E.

In some embodiments, the gate runners 256 may take up a small amount of the area of the first metallization layer 252, increasing the availability of area for the active regions 254. In some embodiments, the gate runners 256 may take up about 10% or less of the area of the first metallization layer 252, such as about 5% or less, such as about 3% or less, such as about 1% or less, such as about 0.5% or less. A gate via 258 may be used to communicate signals to the gate runners 256. The gate via 258 may extend through a central portion of the power semiconductor device 250.

The power semiconductor device 250 may include one or more sensor(s) 255 in the first metallization layer 252. The one or more sensor(s) 255 may be, for instance, temperature sensor(s), current sensor(s), signal resistor(s), or other on-chip sensor(s) 255. Each of the sensor(s) 255 may include sensor vias 257 used to communicate signals to and/or from the sensor(s) 255.

A first insulating layer 260 may be on the first metallization layer 252 (e.g., on the first metallization layer). The first insulating layer 260 may include an insulating portion 262. The insulating portion 262 may be a dielectric material (e.g., a dielectric coating). The insulating portion 262 may be patterned to mask the one or more metal structures of the first metallization layer, including the sensor(s) 255. More particularly, the insulating portion 262 may be patterned to cover certain metal structures in the first metallization layer 252 while leaving other features (e.g., portions of the semiconductor structure 254) uncovered.

For instance, the insulating portion 262 may include masking portions 264 operable to insulate or to mask the gate runners 256 of the first metallization layer. The insulating portion 262 may be patterned to form source contact openings 268. The source contact openings 268 may accommodate source contacts extending from, for instance, a source bond pad 294 on a second metallization layer 290 (e.g., a bonding layer). The gate via 258 and the sensor via(s) 257 may extend through the insulating portion 262 of the insulating layer 260.

In the example of FIG. 10A, the power semiconductor device 250 may include a third metallization layer 270. The third metallization layer 270 may include an insulating portion 272. The insulating portion 272 may be a dielectric material (e.g., dielectric coating). The insulating portion 272 may be patterned in a similar manner as the insulating portion 262 of the first insulating layer 260. For instance, the insulating portion 272 may include masking portions 274 to insulate or to mask the gate runners 256. The insulating portion 272 may include source contact openings 278. The source contact openings 278 may accommodate source contacts extending from, for instance, a source bond pad 294 in the second metallization layer 290 (e.g., a bonding layer).

The third metallization layer 270 may include one or more metal structures. The metal structures may be used, for instance, to route power and/or signal vias to more desirable locations within the power semiconductor device 250. In the example of FIG. 10A, the third metallization layer 270 includes a planar interconnect structure 275 used to route the gate via 208 to a second gate via 276. The third metallization layer 270 includes planar interconnect structure(s) 287 to route the sensor via(s) 257 to the second sensor via(s) 286.

The power semiconductor device 200 may include a second insulating layer 280. The second insulating layer 280 may be on the third metallization layer 270. Similar to the first insulating layer 260, the second insulating layer 280 may include an insulating portion 282. The insulating portion 282 may be a dielectric material (e.g., dielectric coating). The insulating portion 282 may be patterned in a similar manner as the insulating portion 262 of the first insulating layer 260. For instance, the insulating portion 282 may include masking portions 284 to insulate or to mask the gate runners 256. The insulating portion 282 may include source contact openings 288. The source contact openings 288 may accommodate source contacts extending from, for instance, a source bond pad 294 in the second metallization layer 290 (e.g., a bonding layer). The second sensor via(s) 286 may extend through the second insulating layer 280.

The second metallization layer 290 may be on the second insulating layer 280 such that the second insulating layer 280 is between the third metallization layer 270 and the second metallization layer 290. In some embodiments, the second metallization layer 290 may act as a bonding layer for the power semiconductor device 250. In the example of FIG. 10A, the second metallization layer 290 includes a large gate bonding pad 292 at a center edge region of the power semiconductor device 250, which may be a useful location for packaging. The second metallization layer 290 may include a large source bonding pad 294. The second metallization layer 290 may include sensor bonding pad(s) 296 for establishing connections with the sensor(s) 255. Other suitable configurations of the gate bonding pad 292 and the source bonding pad 294 may be used without deviating from the scope of the present disclosure. Example bonding layer configurations are illustrated in FIGS. 11A-11U.

The second metallization layer 290 may be used for interconnection of the power semiconductor device 250 to elements of a semiconductor package, including substrates, lead frames, terminals, etc. Interconnection methods may vary based on package type, but may include wire bonding, soldering, sintering, conductive epoxy, or similar electrically conductive material.

The power semiconductor device 250 may include other structures without deviating from the scope of the present disclosure. For instance, the power semiconductor device 250 may include a backside metallization layer (not shown) including a drain attach pad on the backside of the semiconductor structure 254 to form a vertical structure power semiconductor device 250. The power semiconductor device 250 may include an insulating layer (not shown) on the second metallization layer 290. The power semiconductor device 250 may include an edge termination structure.

FIG. 10B depicts a power semiconductor device 250 similar to the device illustrated in FIG. 10A. In the power semiconductor device 250 of FIG. 10B, the sensor(s) 255 are in the third metallization layer 270. The sensor via(s) 286 provide signal connections to the sensor(s) 255. The sensor via(s) 286 extend through the second dielectric layer 280 to the sensor bond pad(s) 296 in the second metallization layer 290.

FIG. 10C depicts a power semiconductor device 250 similar to the devices illustrated in FIGS. 10A and 10B. In the power semiconductor device of FIG. 10C, the sensor(s) 255 are second metallization layer 290. The second metallization layer 290 may include sensor bonding pad(s) 296 to establish connections with the sensor(s) 255.

As described above, a power semiconductor device having multiple layers of topside metallization according to example embodiments of the present disclosure may provide increased flexibility in how bonding pads (e.g., gate bonding pads, source bonding pads, sensor bonding pads) are incorporated into the power semiconductor device. To this end, there are numerous functional implementations of resizing and positioning signal pads and power pads to make the ideal bonding pad layout for a given packaging approach, all without requiring modification of the first metallization layer of the power semiconductor device. This may deliver increased flexibility and performance.

FIGS. 11A-11U depict example arrangements of bonding pads (e.g., a gate bonding 302 and a source bonding pad 304) on a bonding layer 300 according to examples embodiments of the present disclosure. For any bonding pad feature, the bonding pad may be formed as squares, rounded squares, rounded rectangles, circles, T shapes, L shapes, or similar geometric entity depending on the specific requirements of the device and package. For the following examples in FIGS. 1A-11U, squares are used for simplicity but could readily be changed to another geometric shape without deviating from the scope of the present disclosure.

FIG. 11A-11C depicts single gate pad 302 arrangements. The single gate pad 302 may be arranged in a corner region as shown in FIG. 11A. The single gate pad 302 may be arranged along an edge region (e.g., a center edge region) as shown in FIG. 11B. The single gate pad 302 may be arranged within the body of the bonding layer 300 (e.g., in a center portion of the bonding layer 310) as shown in FIG. 11C. In the case of FIG. 11C, the bonding pad 302 may not necessarily be centered but may be located at some off-center region within the bonding layer 300.

In some examples, as shown in the examples of FIGS. 11D-11G, multiple gate bonding pads 302 may be used for a variety of functions and may be arranged in many ways. For instance, FIG. 11D depicts gate bonding pads 302 arranged on opposing corner regions of the bonding layer 300. FIG. 11E depicts gate bonding pads 302 arranged on opposing edge regions of the bonding layer 300. Having gate bonding pads 302 on opposing sides of the bonding layer 300 may open up package layout flexibility, such as jumper bonds for interconnection, additional bonds for redundancy, and potential to daisy chain devices in parallel with a series of gate bonds.

In some examples, gate bonding pads 302 may be positioned symmetrically about a perimeter of the bonding layer 300 to provide, for instance, increased signal bond flexibility and gate signal distribution. For instance, FIG. 11F depicts gate bonding pads 302 arranged in symmetric corner regions of the bonding layer 300. FIG. 11G depicts gate bonding pads arranged on symmetric edge regions of the bonding layer 300. The example arrangements of FIGS. 11F and 11G in may be useful for ultra-low inductance approaches, as the pattern resembles a coaxial connection in which there is a significant amount of flux cancellation of the magnetic fields. These positions may be well suited for wire bondless attaches in which a substrate or clip is attached directly to the topside of the devices. The substrate may be multiple layers itself such that signal loop inductance is significantly reduced. Alternatively, devices may daisy chained together with multiple jumpers between devices from gate pad 302 to gate pad 302.

In some examples, multiple gate pads 302 or other bonding pads (e.g., source kelvin bonding pad(s), sensor bonding pad(s), or other accessory bonding pad(s)) may be clustered together. For instance, FIG. 11H depicts clustered gate pads 302 at a corner region of the bonding layer 300. FIG. 11I depicts clustered gate pads 302 at an edge region of the bonding layer 300. FIG. 11J depicts clustered gate pads 302 within a body (e.g., a center portion) of the bonding layer 300. Additional bonding pads may be subsequently added in-line with the clusters depending on the number of interconnections needed.

In some examples, the clustered bonding pads are symmetrical in which a gate bonding pad 302 is centered and other bonding pads 306 (e.g., source kelvin bonding pad(s), sensor bonding pad(s), or other accessory bonding pad(s)) are placed on either side of the gate bonding pad 302. For instance, FIG. 11K depicts symmetric clustered bonding pads with a gate bonding pad 302 in the center and other bonding pads 306 on either side of the gate bonding pad 302. FIG. 11L depicts distributed symmetric clustered bonding pads with a gate bonding pad 302 in the center and other bonding pads 306 on either side of the gate bonding pad 302. FIG. 11M depicts wide symmetric clustered bonding pads with a gate bonding pad 302 in the center and other bonding pads 306 on either side of the gate bonding pad 302. The example arrangements of FIGS. 11K-11M may be useful for wire bonding pattern flexibility as it may allow paralleled devices to have more symmetric wire bonding. Dedicated source kelvin pads may be used as masked off features for direct power source attach techniques. The dedicated source kelvin pads may also be useful in the event that source kelvin resistors are implemented.

In some examples, multiple bonding pads may be clustered along opposing sides of the bonding layer 300. For instance, FIG. 11N depicts clustered gate pads 302 in opposing corner regions of the bonding layer 300. FIG. 11O depicts clustered gate pads 302 in opposing edge regions of the bonding layer 300. The example arrangements of the bonding pads of FIGS. 11N and 11O may be useful to either bond out switching signals on one side of the device and sensor signals on the other. The examples of FIGS. 11N and 11O may also be used to provide redundant gate and source kelvin connections to daisy chain devices together.

One benefit of using multiple topside metallization layers for power semiconductor devices may be expanding the size of the gate bonding pads and other signal pads beyond what would be practical if the bonding pads were directly on the semiconductor structure. Increased size bonding pads may facilitate creation of a power semiconductor device that is highly compatible with wire bondless interconnects for both the power and the signal interfaces. Larger gate bonding pads may be more readily attached with soldering, sintering, welding, etc. Larger gate bonding pads may be more compatible with wide ribbon bonds, which are more reliable and have lower inductance than a circular wire.

Example bonding layers 300 with larger gate bonding pads 302 are illustrated in FIGS. 11P-11U. FIG. 11P depicts a larger gate bonding pad 302 in a corner region of the bonding layer 300. FIG. 11Q depicts a larger gate bonding pad 302 in an edge region of the bonding layer 300. FIG. 11R depicts a larger gate bonding pad 302 within the body of the bonding layer 300. FIG. 11S depicts a full edge gate bonding pad 302. FIG. 11T depicts dual large pads 302 on an edge region of the bonding layer 300. FIG. 11U depicts three large pads 302 on an edge region of the bonding layer 300.

For any of the above approaches, signal resistors may be incorporated for the gate and/or source kelvin network. Signal resistors may act to decouple devices in parallel, stabilizing switching transients and oscillations between devices. These oscillations may occur due to differences in the switching rates and voltages between devices, inducing currents in the switching loops. Adding a lumped resistance on-device is an effective method to limit the transient currents that would flow due to these imbalances. Lumped signal resistors may be implemented on the gate bonding pads and/or the source kelvin bonding pads based on the performance requirements of the power semiconductor device. Signal resistors may be added on any of the layers in the power semiconductor device. Similar to other features, if the signal resistors are moved away from the semiconductor structure, then the area these features take up could instead be used for more semiconductor unit cells.

As described above, a power semiconductor device having multiple layers of topside metallization according to example embodiments of the present disclosure may provide increased flexibility in how gate runner networks are incorporated into the power semiconductor device. Gate runners may be used to reduce the distributed impedance of the control switching loop. Gate runners may be considered high speed “highways” of high electrical conductivity until the gate signal is distributed to the individual power semiconductor cells. Gate runners may be distributed around the outer edge regions and through the middle of the device such that the furthest cells from the gate (or similar) pad do not turn on appreciably slower than the ones closest to it.

In power semiconductor devices having a single topside metallization layer, gate runners may have to be carefully balanced with their position and pattern with respect to the gate pad. As an example, an edge gate bonding pad would normally have a long relative path to the furthest sides of the power semiconductor device, so the unit cells on the opposite edge region would need many gate runners to reduce the relative impedance. The gate runners themselves take up space which may otherwise be used for more active area and accordingly lower on-resistances. Multiple topside metallization layers on the power semiconductor device may allow for robust, well distributed gate runners directly on the semiconductor structure itself or on an additional metallization layer in the stack.

In some embodiments, the first metallization layer 310 may include a gate runner network 315 that is coupled to a gate bonding pad through a center gate via 312. FIGS. 12A-12E depict example gate runner networks 315 electrically conductively connected to a center gate via 312 according to example embodiments of the present disclosure.

FIG. 12A depicts a crosshairs gate runner network 315 connected to a center gate via 312. The crosshairs gate runner network 315 includes two gate runners 314 that intersect within a body of the first metallization layer 310 and are about perpendicular to one another. The gate runners 314 may have the same length or different lengths.

FIG. 12B depicts a crosshairs gate runner network 315 with edge spurs 318. More particularly, the crosshairs gate runner network 315 of FIG. 12B may be similar to that of the crosshairs gate runner network of FIG. 12A, except that the gate runner network 315 of FIG. 12B includes edge spurs 318 located at the edge regions of the first metallization layer 310. The gate runner network 315 of FIG. 12B may be connected to a center gate via 312.

FIG. 12C depicts a linear spurs gate runner network 315. The linear spurs gate runner network includes a plurality of linear gate runners 314 throughout the first metallization layer 310. The linear gate runners 314 may be spaced apart from one another at regular or irregular intervals. The linear gate runners 314 may all have the same length or differing lengths. The linear gate runners 314 may be connected to a center gate via 312.

FIG. 12D depicts a crosshairs gate runner network 315 with middle spurs 318. More particularly, the crosshairs gate runner network 315 of FIG. 12B may be similar to that of the crosshairs gate runner network of FIG. 12B, except that the gate runner network 315 of FIG. 12D includes spurs 318 located in the middle of the gate runners 314. The gate runner network 315 of FIG. 12D may be connected to a center gate via 312.

FIG. 12E depicts a branching crosshairs gate runner network 315. More particularly, the crosshairs gate runner network 315 of FIG. 12E may be similar to that of the crosshairs gate runner network of FIG. 12A, except that the gate runner network 315 of FIG. 12E includes branched gate runners 320 located at the edge regions of the first metallization layer 310. The gate runner network 315 of FIG. 12E may be connected to a center gate via 312.

In some embodiments, the first metallization layer on the first metallization layer 310 may include a gate runner network 315 that is coupled to a gate bonding pad through an edge gate via 322. FIGS. 12F-12J depict example gate runner networks 315 electrically conductively connected to an edge gate via 322 according to example embodiments of the present disclosure.

FIG. 12F depicts a perimeter gate runner network 325 with gate runners 324 located along a perimeter of the first metallization layer 310. The perimeter gate runner network 325 may be connected to an edge gate via 322.

FIG. 12G depicts a center gate runner network 325 with a gate runner 326 located in a center portion or within the body of the first metallization layer 310. The center gate runner network 325 may be connected to an edge gate via 322.

FIG. 12H depicts a combined gate runner network 325 with perimeter gate runners 324 along a perimeter of the first metallization layer 310 and a center gate runner 326 located in a center portion or within the body of the first metallization layer 310. The combined gate runner network 325 may be connected to an edge gate via 322.

FIG. 12I depicts a gate runner network 325 with perimeter gate runners 324 along a perimeter of the first metallization layer 310 and multiple center gate runners 326 within the body of the first metallization layer 310. The gate runner network 325 may be connected to an edge gate via 322.

FIG. 12J depicts a branching gate runner network 325 with perimeter gate runners 324 along a perimeter of the first metallization layer 310 and a center gate runner 326 located in a center portion or within the body of the first metallization layer 310. The center gate runner 326 may include branched gate runners 328 located at an edge region of the first metallization layer 310. The branching gate runner network 325 may be connected to an edge gate via 322.

In some examples, the first metallization layer directly on the semiconductor structure of a power semiconductor device may include a distributed gate runner network. The distributed gate runner network may include a plurality of non-contacting gate runners. The non-contacting gate runners may be separated from one another in the first metallization layer such that there is no conductive electrical connection between the non-contacting gate runners in the first metallization layer.

More particularly, the routing of the gate runners takes up space that could otherwise be used as active area. In some cases, such as highly distributed and branching runners, the space may be considerable. Taking advantage of the multiple metallization layers may allow for implementation of a distributed gate runner network. The distributed gate runners may be connected to one another in a different metallization layer (e.g., a third metallization layer). In this way, only vias may be needed at the first metallization layer directly on the semiconductor structure to connect the gate runners to the gate bonding pad of a power semiconductor device. This may be effective at reducing real state for the gate runners and increasing the active region for the power semiconductor device.

FIG. 13 depicts layers of an example power semiconductor device 400 that incorporates a distributed gate runner network according to example embodiments of the present disclosure. More particularly, the power semiconductor device 400 may include a first metallization layer 402. The first metallization layer 402 may be directly on a semiconductor structure 204 with active regions including semiconductor unit cells (e.g., silicon carbide-based MOSFETs or other devices). The first metallization layer 402 may include metal structures, including gate runners 406 and gate vias 408. As used herein, the metal structures directly on the semiconductor structure 404 for metallization, interconnection, gate distribution, edge termination, etc. form the first metallization layer 402.

The gate runners 406 form a distributed gate runner network as the gate runners do not contact one another in the first metallization layer 402. Each of the gate runners 406 may include spurs extending out in multiple directions. Each of the gate runners is coupled to a gate via 408. Other example distributed gate runner networks are illustrated in FIGS. 14A-14E.

In some embodiments, the gate runners 406 may take up a small amount of the area of the first metallization layer 402, increasing the availability of area for the active regions of the semiconductor structure 404. In some embodiments, the gate runners 406 may take up about 10% or less of the area of the first metallization layer 202, such as about 5% or less, such as about 3% or less, such as about 1% or less, such as about 0.5% or less.

A first insulating layer 410 may be on the first metallization layer 402. The first insulating layer 410 may include an insulating portion 412 (e.g., a dielectric coating). The insulating portion 412 may be a dielectric material (e.g., dielectric coating). The insulating portion 412 may be patterned to insulate or to mask the one or more metal structures of the first metallization layer. More particularly, the insulating portion 412 may be patterned to cover certain metal structures in the first metallization layer 402 while leaving other features (e.g., portions of active regions of the semiconductor structure 404) uncovered.

For instance, the insulating portion 412 may include masking portions 414 operable to insulate or to mask the gate runners 406 of the first metallization layer 402. The insulating portion 412 may be patterned to form source contact openings 418. The source contact openings 218 may accommodate source contacts extending from, for instance, a source bond pad 444 on a second metallization layer 440 (e.g., a bonding layer). The insulating portion 412 may include a gate pad portion 416. The gate vias 408 may extend through the insulating portion 412 of the insulating layer 410.

The power semiconductor device 400 may include a third metallization layer 420. The third metallization layer 420 may include an insulating portion 422. The insulating portion 422 may be a dielectric material (e.g., dielectric coating). The insulating portion 422 may be patterned in a similar manner as the insulating portion 412 of the first insulating layer 410. For instance, the insulating portion 422 may include masking portions 424 to insulate or to mask the gate runners 406. The insulating portion 422 may include source contact openings 428. The source contact openings 428 may accommodate source contacts extending from, for instance, a source bond pad 444 in the second metallization layer 440 (e.g., a bonding layer).

The third metallization layer 420 may include one or more metal structures. The metal structures may be used, for instance, to route power and/or signal vias to more desirable locations within the power semiconductor device 400. In the example of FIG. 13, the third metallization layer 420 includes a planar interconnect structure 425 used to route the gate vias 408 to second planar interconnect structure 427. The second planar interconnect structure 427 may be conductively connected to a second gate via 426 that is coupled to the gate bonding pad 442 in the second metallization layer 440 (e.g., the bonding layer).

The power semiconductor device 400 may include a second insulating layer 430. The second insulating layer 430 may be on the third metallization layer 420. Similar to the insulating layer 410, the second insulating layer 430 may include an insulating portion 432. The insulating portion 432 may be a dielectric material (e.g., dielectric coating). The insulating portion 432 may be patterned in a similar manner as the insulating portion 412 of the first insulating layer 410. For instance, the insulating portion 432 may include masking portions 434 to insulate or to mask the gate runners 406. The insulating portion 432 may include source contact openings 438. The source contact openings 428 may accommodate source contacts extending from, for instance, a source bond pad 444 in the second metallization layer 440 (e.g., a bonding layer). The second gate via 426 may extend through the second insulating layer 430.

The second metallization layer 440 may be on the second insulating layer 430 such that the second insulating layer 430 is between the third metallization layer 420 and the second metallization layer 440. In some embodiments, the second metallization layer 440 may act as a bonding layer for the power semiconductor device 400. In the example of FIG. 13, the second metallization layer 440 includes a large gate bonding pad 442 at a center edge region of the power semiconductor device 400, which may be a useful location for packaging. The second metallization layer 440 may include a large source bonding pad 444. Other suitable configurations of the gate bonding pad 442 and the source bonding pad 444 may be used without deviating from the scope of the present disclosure. Example bonding layer configurations are illustrated in FIGS. 11A-11U.

The second metallization layer 440 may be used for interconnection of the power semiconductor device 400 to elements of a semiconductor package, including substrates, lead frames, terminals, etc. Interconnection methods may vary based on package type, but may include wire bonding, soldering, sintering, conductive epoxy, or similar electrically conductive material.

The power semiconductor device 400 may include other structures without deviating from the scope of the present disclosure. For instance, the power semiconductor device 400 may include a backside metallization layer (not shown) including a drain attach pad on the backside of the semiconductor structure 404 to form a vertical structure power semiconductor device 400. The power semiconductor device 400 may include an insulating layer (not shown) on the second metallization layer 440. The power semiconductor device 400 may include an edge termination structure.

FIGS. 14A-14F depict other example distributed gate runner networks 455 in a first metallization layer 452 according to example embodiments of the present disclosure. The distributed gate runner networks 455 each include a plurality of non-contacting gate runners 456 distributed throughout the first metallization layer. The distributed gate runner networks 455 increase the area available for the active region of the semiconductor structure 454.

For instance, in FIG. 14A, the distributed gate runner network 455 may include four non-contacting via shaped gate runners 456 distributed through the first metallization layer 452. Each of the via shaped gate runners 456 may be a point contact directly on the semiconductor structure 454. More or fewer gate runners 456 may be used without deviating from the scope of the present disclosure.

In FIG. 14B, the distributed gate runner network 455 may include four non-contacting gate runners 456 distributed through the first metallization layer 452. Each gate runner 456 may include a plurality of spurs extending in multiple directions, for instance, to form a cross shape. More or fewer gate runners 456 may be used without deviating from the scope of the present disclosure.

In FIG. 14C, the distributed gate runner network 455 may include nine non-contacting via shaped gate runners 456 distributed through the first metallization layer 452. Each of the via shaped gate runners 456 may be a point contact directly on the semiconductor structure 454. More or fewer gate runners 456 may be used without deviating from the scope of the present disclosure.

In FIG. 14D, the distributed gate runner network 455 may include four non-contacting gate runners 456 at the corner regions of the first metallization layer 452. Each gate runner 456 includes two spurs extending in different directions along, for instance a perimeter region of the first metallization layer 452. More or fewer gate runners 456 may be used without deviating from the scope of the present disclosure.

In FIG. 14E, the distributed gate runner network 455 may include four non-contacting gate runners 456 at the corner regions of the first metallization layer 452. Each gate runner 456 includes two spurs extending in different directions along, for instance a perimeter region of the first metallization layer 452. The distributed gate runner network 455 further includes a center gate runner 456 in a center portion or within the body of the first metallization layer 452. The center gate runner 456 may include a plurality of spurs extending in multiple directions, for instance, to form a cross shape. More or fewer gate runners 456 may be used without deviating from the scope of the present disclosure.

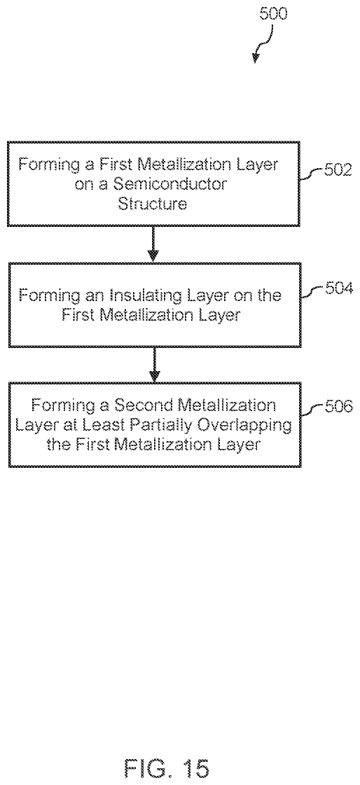

FIG. 15 depicts a flow chart of an example method 500 of forming a power semiconductor device according to example embodiments of the present disclosure, such as the power semiconductor device 150 of FIG. 4. FIG. 15 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At 502, the method 500 may include forming a first metallization layer on a semiconductor structure having an active region. The semiconductor structure may be a silicon carbide-based semiconductor structure or other semiconductor structure (e.g., wide band gap semiconductor structure). The first metallization layer may include one or more metal structures, such as one or more gate runners, gate vias, sensors, or other metal structures. An example first metallization layer formed on a semiconductor structure is illustrated as first metallization layer 152 of FIG. 4.

At 504, the method 500 may include forming an insulating layer on the first metallization layer. The insulating layer may include an insulating portion. The insulating portion may be a dielectric material. The insulating portion may be patterned to insulate or to mask the one or more metal structures of the first metallization layer. The insulating portion may include a source contact opening. The power semiconductor device may include a source contact in the source contact opening. An example insulating layer is illustrated as insulating layer 160 of FIG. 4

At 506, the method 500 may include forming a second metallization layer at least partially overlapping the first metallization layer. The second metallization layer may be a bonding layer and may include a gate bond pad and/or a source bond pad for the power semiconductor device. An example second metallization layer is illustrated as second metallization layer 170 of FIG. 4.

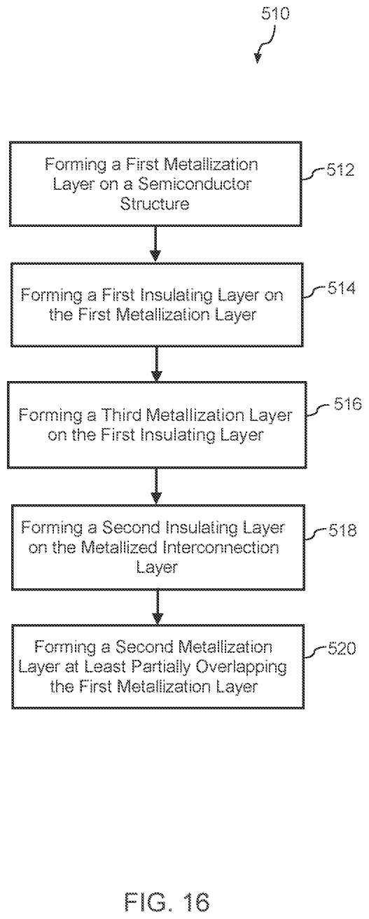

FIG. 16 depicts a flow chart of an example method 510 of forming a power semiconductor device according to example embodiments of the present disclosure, such as the power semiconductor device 200 of FIG. 7. FIG. 16 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

At 512, the method 510 may include forming a first metallization layer on a semiconductor structure having an active region. The semiconductor structure may be a silicon carbide-based semiconductor structure or other semiconductor structure (e.g., wide band gap semiconductor). The first metallization layer may include one or more metal structures, such as one or more gate runners, gate vias, sensors, or other metal structures. An example first metallization layer formed on a semiconductor structure is illustrated as first metallization layer 202 of FIG. 7.

At 514, the method 510 may include forming a first insulating layer on the first metallization layer. The first insulating layer may include an insulating portion. The insulating portion may be a dielectric material. The insulating portion may be patterned to insulate or to mask the one or more metal structures of the first metallization layer. The insulating portion may include a source contact opening. The power semiconductor device may include a source contact in the source contact opening. An example first insulating layer is illustrated as insulating layer 210 of FIG. 7

At 516, the method 510 may include forming a third metallization layer on the first insulating layer. The third metallization layer may include one or more interconnect structures, such one or more planar interconnect structures. The planar interconnect structures may be used to transfer the location of vias, for instance, in the power semiconductor device. In some examples, the third metallization layer may include one or more sensors or other devices. An example third metallization layer is illustrated as third metallization layer 220 of FIG. 7.

At 518, the method may include forming a second insulating layer on the third metallization layer. The second insulating layer may be patterned to insulate or to mask the one or more metal structures in the first metallization layer. The second insulating layer may include a source contact opening. In some examples, a via may extend from the third metallization layer through the second insulating layer. An example second insulating layer is illustrated as second insulating layer 230 of FIG. 7.

At 520, the method 510 may include forming a second metallization layer at least partially overlapping the first metallization layer. The second metallization layer may be a bonding layer and may include a gate bond pad and/or a source bond pad for the power semiconductor device. An example second metallization layer is illustrated as second metallization layer 240 of FIG. 7.

Example aspects of the present disclosure are provided in the following paragraphs, the examples of which may be combined to form various different embodiments of the present disclosure.

One example aspect of the present disclosure is directed to a semiconductor device. The semiconductor device includes a semiconductor vertical power device structure. The semiconductor device includes a first metallization layer on the semiconductor structure. The first metallization layer may include one or more metal structures. The semiconductor device includes a second metallization layer at least partially overlapping the first metallization layer. The semiconductor device includes an insulating layer between the first metallization layer and the second metallization layer. The insulating layer may include an insulating portion. The insulating portion may be patterned to insulate the one or more metal structures of the first metallization layer.

Some examples are directed to a semiconductor device of any preceding paragraph, wherein the insulating layer includes a source contact opening to accommodate a source contact.

Some examples are directed to a semiconductor device of any preceding paragraph, wherein the second metallization layer includes a source bonding pad and a gate bonding pad.

Some examples are directed to a semiconductor device of any preceding paragraph, wherein a third metallization layer is between the insulating layer and the second metallization layer.

Some examples are directed to a semiconductor device of any preceding paragraph, wherein a second insulating layer is between the interconnection layer and the second metallization layer.

Some examples are directed to a semiconductor device of any preceding paragraph, wherein the second insulating layer includes an insulating portion patterned to insulate the one or more metal structures of the first metallization layer.

Some examples are directed to a semiconductor device of any preceding paragraph, wherein the second insulating layer includes a source contact opening to accommodate a source contact.

Some examples are directed to a semiconductor device of any preceding paragraph, wherein the semiconductor device includes a via, the via connected to the one or more metal structures, the via extending through the insulating layer, the via connected to a planar interconnect structure in the second metallization layer.

Some examples are directed to a semiconductor device of any preceding paragraph, wherein the planar interconnect structure is coupled to a gate bonding pad.

Some examples are directed to a semiconductor device of any preceding paragraph, wherein the semiconductor device includes a via, the via connected to the one or more metal structures, the via extending through the insulating layer, the via connected to a planar interconnect structure in the third metallization layer.

Some examples are directed to a semiconductor device of any preceding paragraph, wherein the semiconductor device includes a second via coupled to the planar interconnect structure, the second via electrically coupled to a gate bonding pad.

Some examples are directed to a semiconductor device of any preceding paragraph, wherein the semiconductor device includes a sensor in the first metallization layer.

Some examples are directed to a semiconductor device of any preceding paragraph, wherein the semiconductor device includes a first via connected to the sensor and a second via connected to the sensor, the first via and the second via each extending through the insulating layer.

Some examples are directed to a semiconductor device of any preceding paragraph, wherein the semiconductor device includes a third metallization layer, the first via connected to a first planar interconnect structure in the third metallization layer and the second via connected to a second planar interconnect structure in the third metallization layer.

Some examples are directed to a semiconductor device of any preceding paragraph, wherein the semiconductor device includes a third via connecting the first planar interconnect structure to a first bonding pad in the second metallization layer and a fourth via connecting the second planar interconnect structure to a second bonding pad in the second metallization layer.

Some examples are directed to a semiconductor device of any preceding paragraph, wherein the semiconductor device includes a sensor in the third metallization layer.

Some examples are directed to a semiconductor device of any preceding paragraph, wherein the semiconductor device includes a first via connected to the sensor and a second via connected to the sensor, the first via and the second via each extending through a second insulating layer between the third metallization layer and the second metallization layer, the first via coupled to a first bonding pad in the second metallization layer, the second via coupled to a second bonding pad in the second metallization layer.

Some examples are directed to a semiconductor device of any preceding paragraph, wherein the one or more metal structures include a gate runner.

Some examples are directed to a semiconductor device of any preceding paragraph, wherein the one or more metal structures form a gate runner network.

Some examples are directed to a semiconductor device of any preceding paragraph, wherein the gate runner network includes one or more of a crosshairs gate runner network, a crosshairs gate runner network with edge spurs, a gate runner network with linear spurs, a crosshairs gate runner network with middle spurs, or a crosshairs gate runner network with branched gate runners.

Some examples are directed to a semiconductor device of any preceding paragraph, wherein the gate runner network includes a center gate runner.

Some examples are directed to a semiconductor device of any preceding paragraph, wherein the gate runner network includes one or more perimeter gate runners.

Some examples are directed to a semiconductor device of any preceding paragraph, wherein the gate runner network includes a distributed gate runner network, the distributed gate runner network comprising a plurality of non-contacting gate runners, the non-contacting gate runners being separated from one another in the first metallization layer such that there is no conductive electrical connection between the non-contacting gate runners in the first metallization layer.

Some examples are directed to a semiconductor device of any preceding paragraph, wherein the second metallization layer includes a gate bonding pad in a corner region of the semiconductor device, an edge region of the semiconductor device, or a center region of the semiconductor device.

Some examples are directed to a semiconductor device of any preceding paragraph, wherein the second metallization layer includes a first gate bonding pad and a second gate bonding pad.

Some examples are directed to a semiconductor device of any preceding paragraph, wherein the first gate bonding pad is located in a first corner region of the semiconductor device and the second gate bonding pad is located in a second corner region of the semiconductor device, the first corner region being opposite to the second corner region.

Some examples are directed to a semiconductor device of any preceding paragraph, wherein the first gate bonding pad is located in a first edge region of the semiconductor device and the second gate bonding pad is located in a second edge region of the semiconductor device, the first edge region being opposite the second edge region.

Some examples are directed to a semiconductor device of any preceding paragraph, wherein the first gate bonding pad and the second gate bonding pad are located in a first corner region of the semiconductor device.

Some examples are directed to a semiconductor device of any preceding paragraph, wherein the first gate bonding pad and the second gate bonding pad are located in a first edge region of the semiconductor device.

Some examples are directed to a semiconductor device of any preceding paragraph, wherein the first gate bonding pad and the second gate bonding pad are located in a center region of the semiconductor device.

Another example aspect of the present disclosure is directed to a semiconductor device. The semiconductor device includes a semiconductor structure. The semiconductor device includes a first metallization layer on the semiconductor structure. The first metallization layer includes one or more metal structures. The semiconductor device includes a second metallization layer at least partially overlapping the first metallization layer. The semiconductor device includes a third metallization layer between the first metallization layer and the second metallization layer. The semiconductor device includes a first insulating layer between the first metallization layer and the third metallization layer. The semiconductor device includes a second insulating layer between the third metallization layer and the second metallization layer.

Some examples are directed to a semiconductor device of any preceding paragraph, wherein the first metallization layer includes one or more gate runners.

Some examples are directed to a semiconductor device of any preceding paragraph, wherein the first metallization layer includes a sensor.

Some examples are directed to a semiconductor device of any preceding paragraph, wherein the third metallization layer includes a sensor.

Some examples are directed to a semiconductor device of any preceding paragraph, wherein the third metallization layer includes a planar interconnect structure connecting a first via extending through the first insulating layer to a second via extending through the second insulating layer.

Some examples are directed to a semiconductor device of any preceding paragraph, wherein the second metallization layer includes a gate bonding pad.

Some examples are directed to a semiconductor device of any preceding paragraph, wherein the second metallization layer Some examples are directed to a method of any preceding paragraph, wherein the method includes a source bonding pad.

Some examples are directed to a semiconductor device of any preceding paragraph, wherein the first insulating layer includes an insulating portion, the insulating portion patterned to insulate the one or more gate runners.

Some examples are directed to a semiconductor device of any preceding paragraph, wherein the first insulating layer includes one or more source contact openings to accommodate a source contact.

Some examples are directed to a semiconductor device of any preceding paragraph, wherein the second insulating layer includes an insulating portion, the insulating portion patterned to insulate the one or more gate runners.

Some examples are directed to a semiconductor device of any preceding paragraph, wherein the second insulating layer includes one or more source contact openings to accommodate a source contact connected to the second metallization layer.

Another example aspect of the present disclosure is directed to a semiconductor device. The semiconductor device includes a semiconductor structure. The semiconductor device includes a first metallization layer on the semiconductor structure. The first metallization layer includes a distributed gate runner network. The distributed gate runner network includes a plurality of non-contacting gate runners. The non-contacting gate runners are separated from one another in the first metallization layer such that there is no conductive electrical connection between the non-contacting gate runners in the first metallization layer.

Some examples are directed to a semiconductor device of any preceding paragraph, further comprising a second metallization layer overlapping the first metallization layer.

Some examples are directed to a semiconductor device of any preceding paragraph, wherein the semiconductor device includes a third metallization layer between the first metallization layer and the second metallization layer; a first insulating layer between the first metallization layer and the third metallization layer; and a second insulating layer between the third metallization layer and the first metallization layer.

Some examples are directed to a semiconductor device of any preceding paragraph, wherein the semiconductor device includes a plurality of gate vias, each gate via connected to one of the non-contacting gate runners, each of the gate vias extending through the first insulating layer.

Some examples are directed to a semiconductor device of any preceding paragraph, wherein the third metallization layer includes a planar interconnect structure, at least one of the plurality of gate vias connected to the planar interconnect structure.

Some examples are directed to a semiconductor device of any preceding paragraph, wherein the semiconductor device includes a second via connected to the planar interconnect structure and extending through the second insulating layer.

Some examples are directed to a semiconductor device of any preceding paragraph, wherein the second via is conductively connected to a gate bonding pad in the second metallization layer.

Some examples are directed to a semiconductor device of any preceding paragraph, wherein each of the non-contacting gate runners has a cross shape.

Some examples are directed to a semiconductor device of any preceding paragraph, wherein each of the non-contacting gate runners includes a point contact.

Another example aspect of the present disclosure is directed to a method of forming a semiconductor device. The method includes forming a first metallization layer on a silicon carbide-based semiconductor structure. The first metallization layer includes one or more metal structures. The method includes forming an insulating layer on the first metallization layer. The insulating layer includes an insulating portion. The insulating portion is patterned to insulate the one or more metal structures of the first metallization layer. The method includes forming a second metallization layer overlapping the first metallization layer.

Some examples are directed to a method of any preceding paragraph, wherein the one or more metal structures comprise one or more gate runners.

Some examples are directed to a method of any preceding paragraph, wherein the second metallization layer includes a source bonding pad and a gate bonding pad.

Some examples are directed to a method of any preceding paragraph, wherein the method includes forming a third metallization layer on the insulating layer.

Some examples are directed to a method of any preceding paragraph, wherein the method includes forming a second insulating layer on the third metallization layer.

Some examples are directed to a method of any preceding paragraph, wherein the third metallization layer includes a planar interconnect structure.

Some examples are directed to a method of any preceding paragraph, wherein the insulating layer includes one or more source contact openings.

Some examples are directed to a method of any preceding paragraph, wherein the power semiconductor device includes a source contact in the source contact opening.

Some examples are directed to a method of any preceding paragraph, wherein the first metallization layer includes a sensor.

Some examples are directed to a method of any preceding paragraph, wherein the third metallization layer includes a sensor.

Some examples are directed to a method of any preceding paragraph, wherein the one or more metal structures includes a via.

Some examples are directed to a method of any preceding paragraph, wherein the semiconductor device includes a via contacting the planar interconnect structure and extending through a second insulating layer between the third metallization layer and the second metallization layer.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A semiconductor device, comprising:
a semiconductor vertical power device structure,
a first metallization layer on the semiconductor structure, the first metallization layer comprising one or more metal structures;
a second metallization layer at least partially overlapping the first metallization layer; and
an insulating layer between the first metallization layer and the second metallization layer, the insulating layer comprising an insulating portion, the insulating portion patterned to insulate the one or more metal structures of the first metallization layer.

2. The semiconductor device of claim 1, wherein the insulating layer comprises a source contact opening to accommodate a source contact.

3. The semiconductor device of claim 1, wherein the second metallization layer comprises a source bonding pad and a gate bonding pad.

4. The semiconductor device of claim 1, further comprising a third metallization layer between the insulating layer and the second metallization layer, further comprising a second insulating layer between the third metallization layer and the second metallization layer, wherein the second insulating layer comprises an insulating portion patterned to insulate the one or more metal structures of the first metallization layer.

5. (canceled)

6. (canceled)

7. The semiconductor device of claim 4, wherein the second insulating layer comprises a source contact opening to accommodate a source contact.

8. The semiconductor device of claim 1, further comprising a via, the via connected to the one or more metal structures, the via extending through the insulating layer, the via connected to a planar interconnect structure in the second metallization layer.

9. The semiconductor device of claim 8, wherein the planar interconnect structure is coupled to a gate bonding pad.

10. The semiconductor device of claim 4, further comprising a via, the via connected to the one or more metal structures, the via extending through the insulating layer, the via connected to a planar interconnect structure in the third metallization layer.

11. The semiconductor device of claim 10, further comprising a second via coupled to the planar interconnect structure, the second via electrically coupled to a gate bonding pad.

12. The semiconductor device of claim 1, further comprising a sensor in the first metallization layer.

13. The semiconductor device of claim 12, further comprising a first via connected to the sensor and a second via connected to the sensor, the first via and the second via each extending through the insulating layer.

14. The semiconductor device of claim 13, further comprising a third metallization layer, the first via connected to a first planar interconnect structure in the third metallization layer and the second via connected to a second planar interconnect structure in the third metallization layer.

15. The semiconductor device of claim 14, further comprising a third via connecting the first planar interconnect structure to a first bonding pad in the second metallization layer and a fourth via connecting the second planar interconnect structure to a second bonding pad in the second metallization layer.

16. The semiconductor device of claim 4, further comprising a sensor in the third metallization layer.

17. The semiconductor device of claim 16, further comprising a first via connected to the sensor and a second via connected to the sensor, the first via and the second via each extending through a second insulating layer between the third metallization layer and the second metallization layer, the first via coupled to a first bonding pad in the second metallization layer, the second via coupled to a second bonding pad in the second metallization layer.

18. The semiconductor device of claim 1, wherein the one or more metal structures comprise a gate runner.

19. The semiconductor device of claim 1, wherein the one or more metal structures form a gate runner network.

20.-22. (canceled)

23. The semiconductor device of claim 19, wherein the gate runner network comprises a distributed gate runner network, the distributed gate runner network comprising a plurality of non-contacting gate runners, the non-contacting gate runners being separated from one another in the first metallization layer such that there is no conductive electrical connection between the non-contacting gate runners in the first metallization layer.

24.-41. (canceled)

42. A semiconductor device, comprising:
a semiconductor structure; and
a first metallization layer on the semiconductor structure, the first metallization layer comprising a distributed gate runner network;
wherein the distributed gate runner network comprising a plurality of non-contacting gate runners, the non-contacting gate runners being separated from one another in the first metallization layer such that there is no conductive electrical connection between the non-contacting gate runners in the first metallization layer.

43.-50. (canceled)

51. A method of forming a semiconductor device, the method comprising:
forming a first metallization layer on a silicon carbide-based semiconductor structure, the first metallization layer comprising one or more metal structures;
forming an insulating layer on the first metallization layer, the insulating layer comprising an insulating portion, the insulating portion patterned to insulate the one or more metal structures of the first metallization layer; and
forming a second metallization layer overlapping the first metallization layer.

52.-62. (canceled)
